(19) United States
(12) Patent Application Publication
(10) Pub. No.: US 2025/0098492 A1
(43) Pub. Date: Mar. 20, 2025

(54) DISPLAY PANEL AND DISPLAY DEVICE

(71) Applicant: KUNSHAN GO-VISIONOX OPTO-ELECTRONICS CO., LTD., Kunshan (CN)

(72) Inventors: Won Jun SONG, Kunshan (CN); Deqiang ZHANG, Kunshan (CN); Xiujian ZHU, Kunshan (CN); Mihwa HA, Kunshan (CN); Yu GAO, Kunshan (CN); Wei LI, Kunshan (CN)

(73) Assignee: KUNSHAN GO-VISIONOX OPTO-ELECTRONICS CO., LTD., Kunshan (CN)

(21) Appl. No.: 18/970,955

(22) Filed: Dec. 6, 2024

Related U.S. Application Data
(63) Continuation of application No. PCT/CN2023/134516, filed on Nov. 27, 2023.

(30) Foreign Application Priority Data
Mar. 31, 2023 (CN) 202310356240.4
Apr. 9, 2023 (CN) 202310392090.2
Jun. 26, 2023 (CN) 202310759370.2
Jul. 12, 2023 (CN) 202310854696.3
Jul. 12, 2023 (CN) 202310854718.6
Jul. 12, 2023 (CN) 202310855006.6
Jul. 13, 2023 (CN) 202310855866.X
Sep. 28, 2023 (CN) 202311275756.2

(51) Int. Cl. H10K 59/80; H10K 59/122; H10K 59/38

(52) U.S. Cl. CPC H10K 59/873; H10K 59/122; H10K 59/38; H10K 59/879

(57) ABSTRACT

Disclosed are a display panel and a display device. The display panel includes a substrate, and an isolation structure, a display function layer, a first encapsulation layer, and at least one optical function layer located on the substrate. The isolation structure is located on the substrate and has a first end portion and a second end portion, the second end portion is located on a side, away from the substrate, of the first end portion, and the isolation structure defines a plurality of first openings. The display function layer is located on the substrate and includes a plurality of light-emitting devices correspondingly located in the plurality of first openings, and the light-emitting device includes a first electrode, a light-emitting function layer, and a second electrode stacked on the substrate, and each of the plurality of first openings limits one of the plurality of light-emitting devices.

### CROSS-REFERENCE TO RELATED DISCLOSURES

The present disclosure is a continuation of International Application No. PCT/CN2023/134516, filed on Nov. 27, 2023, which claims priority to Chinese Patent Application No. 202310855006.6 filed on Jul. 12, 2023, Chinese Patent Application No. 202310854696.3 filed on Jul. 12, 2023, Chinese Patent Application No. 202310854718.6 filed on Jul. 12, 2023, Chinese Patent Application No. 202310855866.X filed on Jul. 13, 2023, Chinese Patent Application No. 202310356240.4 filed on Mar. 31, 2023, Chinese Patent Application No. 202311275756.2 filed on Sep. 28, 2023, Chinese Patent Application No. 202310392090.2 filed on Apr. 9, 2023, and Chinese Patent Application No. 202310759370.2 filed on Jun. 26, 2023. The disclosures of the aforementioned applications are hereby incorporated by reference in their entireties.

### TECHNICAL FIELD

Embodiments of the present disclosure relate to the field of display technologies, and in particular, to a display panel and a display device.

### BACKGROUND

Organic Light-Emitting Diode (OLED) is an organic thin-film electrolight-emitting device, and is greatly concerned by people and is widely applied in electronic display products, due to advantages of OLED of low power consumption, high brightness, wide viewing angle, high contrast, flexible display, and the like.

However, current electronic display products are limited to a design of structure of the current electronic display products, facing need for further improving pixel density.

### SUMMARY

A first aspect of the present disclosure provides a display panel, and the display panel includes a substrate, and an isolation structure, a display function layer, a first encapsulation layer, and at least one optical function layer located on the substrate. The isolation structure is located on the substrate and has a first end portion and a second end portion, the second end portion is located on a side, away from the substrate, of the first end portion, an orthographic projection of the first end portion on the substrate is within an orthographic projection of the second end portion on the substrate, and the isolation structure defines a plurality of first openings. The display function layer is located on the substrate and includes a plurality of light-emitting devices correspondingly located in the plurality of first openings, the light-emitting device includes a first electrode, a light-emitting function layer and a second electrode stacked on the substrate, and each of the plurality of first openings limits one of the plurality of light-emitting devices. The first encapsulation layer is located on a side, away from the substrate, of the display function layer. The optical function layer is located on a side, away from the substrate, of the light-emitting function layer and including a plurality of optical function units. An orthographic projection of a part of an edge portion of a part of film layers of the light-emitting device on the substrate is within the orthographic projection of the second end portion on the substrate.

A second aspect of the present disclosure provides a display panel, the display panel includes a substrate, an isolation structure and a display function layer located on the substrate, where the isolation structure has a first end portion and a second end portion, the second end portion is located on a side, away from the substrate, of the first end portion, the isolation structure defines a plurality of first openings, the display function layer includes a plurality of light-emitting devices correspondingly located in the plurality of first openings, a light-emitting device includes a first electrode, a light-emitting function layer and a second electrode stacked on the substrate, an orthographic projection of the light-emitting function layer on the substrate is located outside an orthographic projection of the first end portion on the substrate, and is located within an orthographic projection of the second end portion on the substrate, a distance between edges of first electrodes of adjacent light-emitting devices in contact with corresponding light-emitting function layers is a pixel pitch, and the pixel pitch ranges from 2000-18000 nm.

In an embodiment of the second aspect of the present disclosure, on a right section of the light-emitting device, a cross-sectional profile of a portion, located between two adjacent sub-pixels, of the partition portion is of an inverted trapezoid, an edge of a bottom of the inverted trapezoidal is an edge of the second end portion, and an edge of a top of the inverted trapezoidal is an edge of the first end portion, where a width of the top the inverted trapezoid ranges from 1500-16000 nm.

In another embodiment of the second aspect of the present disclosure, the partition portion includes a support portion and a block portion stacked on the substrate, the support portion forms the first end portion, the block portion forms the second end portion, and on a right section of the light-emitting device, cross-sectional profiles of portions of the support portion and the block portion located between two adjacent sub-pixels are both of a normal trapezoid, an edge of the second end portion is an edge, facing a surface of the substrate, of the block portion, and an edge of the first end portion is an edge, facing the surface of the substrate, of the support portion, where a width of a bottom of a normal trapezoid corresponding to the support portion ranges from 1258-17000 nm, and a width of a top of a normal trapezoid corresponding to the support portion ranges from 880-15000 nm.

In an embodiment of the second aspect of the present disclosure, the display panel may include a plurality of pixels, and each pixel includes a plurality of sub-pixels emitting light of different wavelengths, the plurality of sub-pixels of the plurality of pixels include a first sub-pixel, a second sub-pixel, and a third sub-pixel, and the first sub-pixel, the second sub-pixel, and the third sub-pixel respectively include a light-emitting device different from others.

Optionally, a number ratio of the first sub-pixel, the second sub-pixel, and the third sub-pixel is 1:1:1.

Optionally, in each pixel, the first sub-pixel, the second sub-pixel, and the third sub-pixel are arranged in a first pixel arrangement manner where the first sub-pixel, the second sub-pixel, and the third sub-pixel are arranged in parallel; alternatively, in each pixel, the first sub-pixel, the second sub-pixel, and the third sub-pixel are arranged in a second arrangement manner where the second sub-pixel and the third sub-pixel are arranged in a column or a row and arranged in parallel with the first sub-pixel.

Optionally, the greater a pixel density, at least one of: the less a pixel pitch and the less an average width of the sub-pixels.

In an embodiment of the second aspect of the present disclosure, the partition portion of the isolation structure is in direct contact with the substrate, an edge of a first distance is an edge of a portion of the first electrode contacting the light-emitting function layer in the same light-emitting device, a distance between an orthographic projection of the edge of the second end portion on a surface where the substrate is located and an orthographic projection of the edge of the first end portion on the surface where the substrate is located is a first width, and a distance between the edge of the portion of the first electrode contacting the light-emitting function layer in the same light-emitting device and the orthographic projection of the edge of the second end portion on the surface where the substrate is located is the first distance. In this case, the pixel pitch ranges from 2000-2200 nm, the first distance ranges from 0-1017 nm, and the first width ranges from 148-417 nm; alternatively, the pixel pitch ranges from 2200-2500 nm, the first distance ranges from 0-1050 nm, and the first width ranges from 166-450 nm; alternatively, the pixel pitch ranges from 2500-3200 nm, the first distance ranges from 0-1090 nm, and the first width ranges from 185-490 nm; alternatively, the pixel pitch ranges from 3200-4000 nm, the first distance ranges from 0-1130 nm, and the first width ranges from 203-530 nm; alternatively, the pixel pitch ranges from 4000-6000 nm, the first distance ranges from 0-1170 nm, and the first width ranges from 221-570 nm; alternatively, the pixel pitch ranges from 6000-9000 nm, the first distance ranges from 0-1210 nm, and the first width ranges from 240-610 nm; alternatively the pixel pitch ranges from 9000-13000 nm, the first distance ranges from 0-1300 nm, and the first width ranges from 259-700 nm; alternatively, the pixel pitch ranges from 13000-18000 nm, the first distance ranges from 0-1410 nm, and the first width ranges from 277-810 nm.

For example, on the right section of the light-emitting device, a product of a cotangent value of an acute angle formed by intersection of a line connecting the edge of the light-emitting function layer and the edge of the second end portion with the surface where the substrate is located, and a distance between a middle portion of a lower surface of the light-emitting function layer and the edge of the second end portion in a direction perpendicular to the surface where the substrate is located, is less than or equal to a distance between an orthographic projection of the edge of the first electrode on the substrate and an orthographic projection of the edge of the second end portion on the substrate. For example, the pixel pitch ranges from 2000-2200 nm, and the first distance ranges from 148-567 nm; alternatively, the pixel pitch ranges from 2200-2500 nm, and the first distance ranges from 166-650 nm; alternatively, the pixel pitch ranges from 2500-3200 nm, and the first distance ranges from 185-740 nm; alternatively, the pixel pitch ranges from 3200-4000 nm, and the first distance ranges from 203-830 nm; alternatively, the pixel pitch ranges from 4000-6000 nm, and the first distance ranges from 221-920 nm; alternatively, the pixel pitch ranges from 6000-9000 nm, and the first distance ranges from 240-1010 nm; alternatively, the pixel pitch ranges from 9000-13000 nm, and the first distance ranges from 259-1150 nm; alternatively, the pixel pitch ranges from 13000-18000 nm, the first distance ranges from 277-1310 nm.

For example, further, in a direction perpendicular to the surface where the substrate is located, a distance from the edge of the second end portion to the edge of the first end portion is a first height, and the first height ranges from 400-2200 nm. Optionally, the pixel pitch ranges from 2000-2200 nm, and the first height ranges from 400-800 nm; alternatively, the pixel pitch ranges from 2200-2500 nm, and the first height ranges from 450-850 nm; alternatively, the pixel pitch ranges from 2500-3200 nm, and the first height ranges from 500-900 nm; alternatively, the pixel pitch ranges from 3200-4000 nm, and the first height ranges from 550-950 nm; alternatively, the pixel pitch ranges from 4000-6000 nm, and the first height ranges from 600-1000 nm; alternatively, the pixel pitch ranges from 6000-9000 nm, and the first height ranges from 650-1100 nm; alternatively, the pixel pitch ranges from 9000-13000 nm, and the first height ranges from 700-1200 nm; alternatively, the pixel pitch ranges from 13000-18000 nm, and the first height ranges from 750-22000 nm.

For example, on the right section of the light-emitting device, the distance between the orthographic projection of the edge of the first electrode on the substrate and the orthographic projection of the edge of the second end portion on the substrate is less than: the product of the cotangent value of the acute angle formed by intersection of the line connecting the edge of the light-emitting function layer and the edge of the second end portion with the surface where the substrate is located, and the distance between the middle portion of the lower surface of the light-emitting function layer and the edge of the second end portion in the direction perpendicular to the surface where the substrate is located. In this case, the pixel pitch ranges from 2000-2200 nm, the first distance ranges from 0-415 nm, and the first width ranges from 148-417 nm; alternatively, the pixel pitch ranges from 2200-2500 nm, the first distance ranges from 0-446 nm, and the first width ranges from 166-450 nm; alternatively, the pixel pitch ranges from 2500-3200 nm, the first distance ranges from 0-484 nm, and the first width ranges from 185-490 nm; alternatively, the pixel pitch ranges from 3200-4000 nm, the first distance ranges from 0-522 nm, and the first width ranges from 203-530 nm; alternatively, the pixel pitch ranges from 4000-6000 nm, the first distance ranges from 0-560 nm, and the first width ranges from 221-570 nm; alternatively, the pixel pitch ranges from 6000-9000 nm, the first distance ranges from 0-598 nm, and the first width ranges from 240-610 nm; alternatively, the pixel pitch ranges from 9000-13000 nm, the first distance ranges from 0-685 nm, and the first width ranges from 259-700 nm; alternatively, the pixel pitch ranges from 13000-18000 nm, the first distance ranges from 0-790 nm, and the first width ranges from 277-810 nm.

Optionally, the display panel further includes at least one optical function layer, the optical function layer is located on a side, away from the substrate, of the light-emitting function layer and includes a plurality of optical function units located in the plurality of first openings, a thickness of an edge portion of a part of film layers of an optical function unit gradually decreases, and for every two adjacent first electrodes, the pixel pitch between edges of portions of first electrodes in contact with light-emitting function layers in the same light-emitting devices ranges from 2074-18000 nm.

In an embodiment of the second aspect of the present disclosure, the display panel further includes a pixel defining layer, where the pixel defining layer is located on the first electrode and located on a side, facing the substrate, of the partition portion and defines a second opening, the pixel defining layer covers an edge of the first electrode, the second opening exposes the first electrode, and an edge of the second opening coincides with the edge of portion of first electrode in contact with light-emitting function layer in the same light-emitting device, where a distance between an orthographic projection of the edge of the second end portion on a surface where the substrate is located and an orthographic projection of the edge of the first end portion on the surface where the substrate is located is a first width, and a distance between the edge of the portion of the first electrode contacting the light-emitting function layer in the same light-emitting device and the orthographic projection of the edge of the second end portion on the surface where the substrate is located is the first distance. For example, the pixel pitch ranges from 2200-2500 nm, the first distance ranges from 0-1050 nm, and the first width ranges from 148-450 nm; alternatively, the pixel pitch ranges from 2500-3200 nm, the first distance ranges from 0-1090 nm, and the first width ranges from 185-490 nm; alternatively, the pixel pitch ranges from 3200-4000 nm, the first distance ranges from 0-1130 nm, and the first width ranges from 203-530 nm; alternatively, the pixel pitch ranges from 4000-6000 nm, the first distance ranges from 0-1170 nm, and the first width ranges from 221-570 nm; alternatively, the pixel pitch ranges from 6000-9000 nm, the first distance ranges from 0-1210 nm, and the first width ranges from 240-610 nm; alternatively the pixel pitch ranges from 9000-13000 nm, the first distance ranges from 0-1300 nm, and the first width ranges from 259-700 nm; alternatively the pixel pitch ranges from 13000-18000 nm, the first distance ranges from 0-1410 nm, and the first width ranges from 277-810 nm.

Optionally, on the right section of the light-emitting device, the product of the cotangent value of the acute angle formed by intersection of the line connecting the edge of the light-emitting function layer and the edge of the second end portion with the surface where the substrate is located, and the distance between the middle portion of the lower surface of the light-emitting function layer and the edge of the second end portion in the direction perpendicular to the surface where the substrate is located, is less than or equal to a distance between an orthographic projection of an edge of the first electrode exposed from the second opening on the substrate and the orthographic projection of the edge of the second end portion on the substrate. For example, the pixel pitch ranges from 2200-2500 nm, the first distance ranges from 148-650 nm, and the first width ranges from 148-450 nm; alternatively, the pixel pitch ranges from 2500-3200 nm, the first distance ranges from 185-740 nm, and the first width ranges from 185-490 nm; alternatively, the pixel pitch ranges from 3200-4000 nm, the first distance ranges from 203-830 nm, and the first width ranges from 203-530 nm; alternatively, the pixel pitch ranges from 4000-6000 nm, the first distance ranges from 221-920 nm, and the first width ranges from 221-570 nm; alternatively, the pixel pitch ranges from 6000-9000 nm, the first distance ranges from 240-1010 nm, and the first width ranges from 240-610 nm; alternatively, the pixel pitch ranges from 9000-13000 nm, the first distance ranges from 259-1150 nm, and the first width ranges from 259-700 nm; alternatively, the pixel pitch ranges from 13000-18000 nm, the first distance ranges from 277-1310 nm, and the first width ranges from 277-810 nm.

For example, in a direction perpendicular to the surface where the substrate is located, a distance from the edge of the second end portion to the edge of the first end portion is a first height, and the first height ranges from 400-2200 nm. Optionally, the pixel pitch ranges from 2200-2500 nm, and the first height ranges from 400-850 nm; alternatively, the pixel pitch ranges from 2500-3200 nm, and the first height ranges from 500-900 nm; alternatively, the pixel pitch ranges from 3200-4000 nm, and the first height ranges from 550-950 nm; alternatively, the pixel pitch ranges from 4000-6000 nm, and the first height ranges from 600-1000 nm; alternatively, the pixel pitch ranges from 6000-9000 nm, and the first height ranges from 650-1100 nm; alternatively, the pixel pitch ranges from 9000-13000 nm, and the first height ranges from 700-1200 nm; alternatively, the pixel pitch ranges from 13000-18000 nm, and the first height ranges from 750-22000 nm.

Optionally, on the right section of the light-emitting device, the distance between the orthographic projection of the edge of the first electrode exposed from the second opening on the substrate and the orthographic projection of the edge of the second end portion on the substrate is less than: the product of the cotangent value of the acute angle formed by intersection of the line connecting an edge of the light-emitting function layer and the edge of the second end portion with the surface where the substrate is located, and a distance between the middle portion of the lower surface of the light-emitting function layer and the edge of the second end portion in the direction perpendicular to the surface where the substrate is located. For example, the pixel pitch ranges from 2200-2500 nm, the first distance ranges from 0-446 nm, and the first width ranges from 148-450 nm; alternatively, the pixel pitch ranges from 2500-3200 nm, the first distance ranges from 0-484 nm, and the first width ranges from 185-490 nm; alternatively, the pixel pitch ranges from 3200-4000 nm, the first distance ranges from 0-522 nm, and the first width ranges from 203-530 nm; alternatively, the pixel pitch ranges from 4000-6000 nm, the first distance ranges from 0-560 nm, and the first width ranges from 221-570 nm; alternatively, the pixel pitch ranges from 6000-9000 nm, the first distance ranges from 0-598 nm, and the first width ranges from 240-610 nm; alternatively, the pixel pitch ranges from 9000-13000 nm, the first distance ranges from 0-685 nm, and the first width ranges from 259-700 nm; alternatively, the pixel pitch ranges from 13000-18000 nm, the first distance ranges from 0-790 nm, and the first width ranges from 277-810 nm.

In an embodiment of the second aspect of the present disclosure, the display panel further includes at least one optical function layer, each of the at least one optical function layer is located on a side, away from the substrate, of the light-emitting function layer and includes a plurality of optical function units located in first openings, a thickness of an edge portion of a part of film layers of the optical function unit gradually decreases, and for every two adjacent first electrodes, the pixel pitch between edges of portions of first electrodes in contact with light-emitting function layers in the same light-emitting devices ranges from 2274-18000 nm.

The third aspect of the present disclosure provides a display device, and the display device may include the display panel mentioned in any embodiment of the first aspect or the second aspect.

### BRIEF DESCRIPTION OF THE DRAWINGS

FIG. 1 is a schematic diagram of a planar structure of a display panel according to an embodiment of the present disclosure.

FIG. 2 is a partially enlarged schematic diagram of an S area of the display panel shown in FIG. 1.

FIG. 3 is a cross-sectional view of a partial structure of a sub-pixel in a design of the display panel shown in FIG. 1 and FIG. 2, corresponding to a cross-section of FIG. 2 along M1-N1.

FIG. 4 is an enlarged view of a partial structure of a pixel of a display panel according to an embodiment of the present disclosure, and a cross-sectional view along M2-N2 may be referred to FIG. 3.

FIG. 5 is an enlarged view of a partial structure of a pixel of a display panel according to an embodiment of the present disclosure, and a cross-sectional view along M3-N3 may be referred to FIG. 3.

FIG. 6 is a cross-sectional view of a partial structure of a partial area of a display panel according to an embodiment of the present disclosure.

FIG. 7 is a cross-sectional view of a partial structure of a partial area of a display panel according to another embodiment of the present disclosure.

FIG. 8 is a cross-sectional view of a partial structure of a partial area of a display panel according to another embodiment of the present disclosure.

FIG. 9 is a cross-sectional view of a partial structure of a partial area of a display panel according to another embodiment of the present disclosure.

FIG. 10 is a cross-sectional view of a partial structure of a partial area of a display panel according to another embodiment of the present disclosure.

FIG. 11A is a cross-sectional view of a partial structure of a partial area of a display panel according to another embodiment of the present disclosure.

FIG. 11B is a cross-sectional view of a partial structure of a partial area of a display panel according to another embodiment of the present disclosure.

FIG. 11C is a cross-sectional view of a partial structure of a partial area of a display panel according to another embodiment of the present disclosure.

FIG. 12 is a cross-sectional view of a partial structure of a partial area of a display panel according to another embodiment of the present disclosure.

FIG. 13A is a cross-sectional view of a partial structure of a partial area of a display panel according to another embodiment of the present disclosure.

FIG. 13B is a cross-sectional view of a partial structure of a partial area of a display panel according to another embodiment of the present disclosure.

FIG. 13C is a cross-sectional view of a partial structure of a partial area of a display panel according to another embodiment of the present disclosure.

FIG. 14 is a cross-sectional view of a partial structure of a partial area of a display panel according to another embodiment of the present disclosure.

FIG. 15 is a cross-sectional view of a partial structure of a partial area of a display panel according to another embodiment of the present disclosure.

FIG. 16A is a cross-sectional view of a partial structure of the display panel shown in FIG. 3.

FIG. 16B is a cross-sectional view of a partial structure of a partial area of a display panel according to another embodiment of the present disclosure.

FIG. 17 is a cross-sectional view of a partial structure of a partial area of a display panel according to another embodiment of the present disclosure.

FIG. 18A is a cross-sectional view of a partial structure of a partial area of a display panel according to another embodiment of the present disclosure.

FIG. 18B is a cross-sectional view of a partial structure of a partial area of a display panel according to another embodiment of the present disclosure.

FIG. 19 is a cross-sectional view of a partial structure of a partial area of a display panel according to another embodiment of the present disclosure.

FIG. 20 is a cross-sectional view of a partial structure of a partial area of a display panel according to another embodiment of the present disclosure.

FIG. 21 is a cross-sectional view of a partial structure of a partial area of a display panel according to another embodiment of the present disclosure.

FIG. 22 is a cross-sectional view of a partial structure of a partial area of a display panel according to another embodiment of the present disclosure.

FIG. 23 is a cross-sectional view of a partial structure of a partial area of a display panel according to another embodiment of the present disclosure.

FIG. 24A is a cross-sectional view of a partial structure of a partial area of a display panel according to another embodiment of the present disclosure.

FIG. 24B is a cross-sectional view of a partial structure of a partial area of a display panel according to another embodiment of the present disclosure.

FIG. 25A is a cross-sectional view of a partial structure of a partial area of a display panel according to another embodiment of the present disclosure.

FIG. 25B is a cross-sectional view of a partial structure of a partial area of a display panel according to another embodiment of the present disclosure.

FIG. 26 is a cross-sectional view of a partial structure of a partial area of a display panel according to another embodiment of the present disclosure.

FIG. 27 is an enlarged view of a partial structure of a pixel of a display panel according to an embodiment of the present disclosure.

FIG. 28 is a cross-sectional view of a partial structure of a partial area of a display panel according to another embodiment of the present disclosure.

FIG. 29 is a cross-sectional view of a partial structure of a partial area of a display panel according to another embodiment of the present disclosure.

### DETAILED DESCRIPTIONS OF THE EMBODIMENTS

The technical schemes in the embodiments of the present disclosure will be described clearly and completely below in combination with the accompanying drawings in the embodiments of the present disclosure. Obviously, the described embodiments are only a part of the embodiments of the present disclosure, not all of the embodiments. Based on the embodiments in the present disclosure, all other embodiments obtained by those skilled in the art without creative efforts shall fall within the protection scope of the present disclosure.

Among display products, some function film layers in light-emitting devices are formed by evaporation, there are a plurality of function film layers in each light-emitting device, and materials of some function film layers (such as a light-emitting layer) in light-emitting devices emitting different light are different. Therefore, when these function film layers are evaporated through a mask plate (such as a Fine Metal Mask, FMM), multiple alignment is needed. To solve a problem of positional deviation caused by an alignment accuracy error, sufficient space (a safety margin related to an alignment error) needs to be reserved between different light-emitting devices to ensure a certain overlap rate of an actual position of a light-emitting area of the light-emitting device may and a design position (a design area). The design area of the light-emitting area of the light-emitting device is equivalent to being compressed. The light-emitting area of the light-emitting device is limited, and an arrangement density of the light-emitting device (corresponding to the sub-pixel) may not be further increased, thereby making it difficult to further improve the pixel density of the display panel.

In the present disclosure, an isolation structure is provided at a gap of light-emitting devices to isolate function film layers of adjacent light-emitting devices. Therefore, in an evaporation process of a plurality of function film layers, only an entire surface evaporation needs to be performed on the display panel, and the area where the light-emitting device is located does not need to be evaporated by means of a mask to form the function film layer. Therefore, a process of using the isolation structure for evaporation does not need to consider the alignment accuracy problem during evaporation, so that the gap of the light-emitting devices may be designed to be less in size to increase the pixel density (the principle thereof may be referred to related description of embodiments related to FIG. 10 to FIG. 13 below).

In the above design, the isolation structure surrounds the light-emitting device, and in the evaporation process, due to an evaporation angle of an evaporation source used for evaporation of the function film layer, a height and width of the isolation structure affects distribution of an evaporated film layer. A light-emitting efficiency of the light-emitting area of the light-emitting device is related to evaporation quality of the function film layers, because existence of the evaporation angle during evaporation and shielding of an evaporation material by the isolation structure, in an edge area of the function film layer (such as a first function layer, a light-emitting layer, a second light-emitting layer, and a second electrode), a thickness of the function film layer gradually decreases, thereby affecting the light-emitting efficiency. Therefore, a portion of the function film layer having a uniform thickness is distributed as much as possible in the light-emitting area to ensure any position of the light-emitting area of the light-emitting device having a relatively high light-emitting efficiency, so that the light-emitting area integrally emits light uniformly. Therefore, in practice, the portion (an effective function area below) of the function film layer having a uniform thickness limits a design boundary of the light-emitting area (not necessarily overlapping), that is, a boundary of the effective function area may be obtained first to further determine a boundary of a main light-emitting area (with uniform light-emitting efficiency, and may emit high-quality light) in the light-emitting area.

A range of the effective function area is limited by the light-emitting function layer, and the light-emitting area and the main light-emitting area of the display component are limited by both the light-emitting function layer and a first electrode. For example, taking the light-emitting function layer to define the effective function area as an example, an area where a portion of the function film layer has a uniform thickness is the effective function area; an area where the first electrode and the light-emitting function layer in the light-emitting device are in contact corresponds to a light-emitting area of the light-emitting device; and an area where the first electrode and the effective function area in the light-emitting device overlap and are in contact is the main light-emitting area (emitting light uniformly) of the light-emitting device.

When dimensions of the light-emitting device and the isolation structure are designed, how to plan a height, width, and other parameters of the isolation structure based on factors such as the evaporation angle and a distribution position of the function film layer, in order to maintain a good light-emitting efficiency of the light-emitting devices and enable the light-emitting device to have a relatively less spacing to increase PPI, has become an important research topic in display panel structure design.

In addition, for display panels with different display modes and a specific function requirement in the display panel, the isolation structure is modified or other function structures are provided based on the isolation structure (such as a light conversion layer in the following embodiment). In this case, the height and parameters of the isolation structure need to be adjusted, so that when the function structure is formed by means of the isolation structure, a preparation cost may be reduced, a related error may be reduced, and the pixel density of the product may be improved.

Embodiments of the present disclosure provide a display panel and a display device to at least solve part of the above-mentioned technical problem. The display panel includes a substrate, and an isolation structure, a display function layer, a first encapsulation layer, and at least one optical function layer located on the substrate. The isolation structure is located on the substrate and has a first end portion and a second end portion, the second end portion is located on a side, away from the substrate, of the first end portion, an orthographic projection of the first end portion on the substrate is within an orthographic projection of the second end portion on the substrate, and the isolation structure defines a plurality of first openings. The display function layer is located on the substrate and includes a plurality of light-emitting devices located in corresponding first openings, and the light-emitting device includes a first electrode, a light-emitting function layer, and a second electrode stacked on the substrate, and the first opening limits a corresponding light-emitting device. The first encapsulation layer is located on a side, away from the substrate, of the display function layer. The optical function layer is located on a side, away from the substrate, of the light-emitting function layer, and includes a plurality of optical function units. An orthographic projection of a part of an edge portion of a part of film layers of the light-emitting device on the substrate is within the orthographic projection of the second end portion on the substrate.

The structure of the display panel in at least one embodiment of the present disclosure is described in detail below with reference to the accompanying drawings. In addition, in these drawings, a spatial rectangular coordinate system is established based on the substrate to more intuitively present positional relationships of relevant structures in the display panel. In the spatial rectangular coordinate system, an X-axis and a Y-axis are parallel to a surface where the substrate is located, and a Z-axis is perpendicular to the surface where the substrate is located. Directions of “upper” and “lower” may be determined based on the substrate, for example, a direction, facing a display side (such as a side, away from the substrate, of the light-emitting device), of the substrate represents the “upper” direction, while a direction, away from the display side, of the substrate represents the “lower” direction. For example, if a first object is located between a second object and the substrate, then the second object is above the first object and the first object is below the second object.

In the following embodiments, arrangement manners of the isolation structure of the display panel are described to briefly introduce the principle of the isolation structure improving the pixel density of the display panel, and then based on this, in the case of providing an optical function layer for the display panel, how to provide the pixel pitch (related to the pixel density) to improve the pixel density of the display panel.

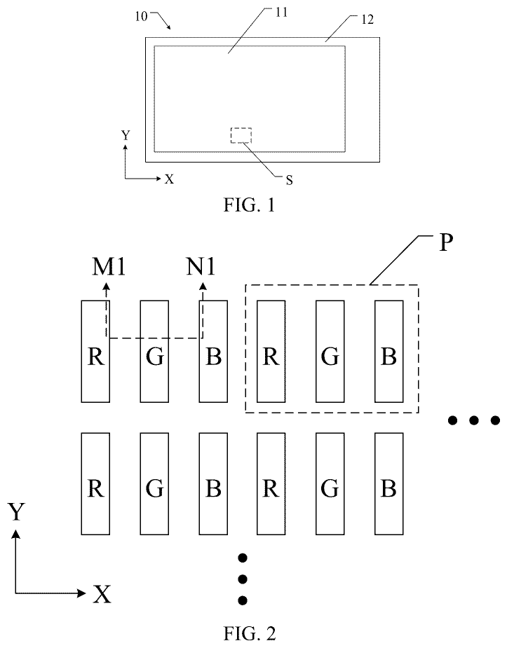

As shown in FIG. 1 to FIG. 29, a planar area of the display panel 10 may be divided into a display area 11 and a bezel area 12 surrounding the display area 11. Sub-pixels, such as R, G, and B, may be arranged in the display area 11, and a physical structure of the sub-pixel may be a light-emitting device. Adjacent sub-pixels with different colors of emergent light may constitute a pixel P (may be referred to as a pixel unit, a large pixel, and the like), and an arrangement density of the pixel P in the display area 11 represents the pixel density. In some embodiments according to the present disclosure, part of wiring in the bezel area 12 may be arranged to the display area 11, so that the bezel area 12 may be designed as a single-sided bezel.

At least in the display area 11, a physical structure of the display panel 10 may include a substrate 100, and an isolation structure 300, a display function layer 20, a first encapsulation layer 510 and at least one optical function layer 40 located on the substrate 100. The isolation structure 300 includes a partition portion 30 located on the substrate 100, and the partition portion 30 has a first end portion 310 and a second end portion 320. The second end portion 320 is located on a side, away from the substrate 100, of the first end portion 310, an orthographic projection of the first end portion 310 on the substrate 100 is within an orthographic projection of the second end portion 320 on the substrate 100, and the partition portion 30 defines a plurality of first openings 301. The display function layer 20 is located on the substrate 100 and includes a plurality of light-emitting devices 200 located in corresponding first openings 301, the light-emitting device 200 includes a first electrode 210, a light-emitting function layer 220, and a second electrode 230 stacked on the substrate 100, and the first opening 301 limits a corresponding light-emitting device 200. The first encapsulation layer 510 is located on a side, away from the substrate 100, of the display function layer 20. An orthographic projection of a part of an edge portion of a part of film layers of the light-emitting device 200 on the substrate 100 is within the orthographic projection of the second end portion 320 on the substrate 100. The optical function layer 40 may include an optical conversion layer 400, and an optical function unit 41 may include an optical conversion unit 410. When the light-emitting devices of the display panel are configured to emit light of the same color (the same color may be single primary color light or mixed light), the light conversion layer 400 is provided in the display panel to enable the display panel to have a light conversion function to display a color image and in this design, light-emitting quality of the display panel may be higher.

For example, the light-emitting function layer may further include a light-emitting layer 222 and a second function layer 223, and the first function layer 221, the light-emitting layer 222, and the second function layer 223 are stacked sequentially on the first electrode 210. The first function layer 221 may include a hole injection layer, a hole transport layer, an electron block layer, and the like. The second function layer 223 may include an electron injection layer, an electron transport layer, a hole block layer, and the like.

In an embodiment of the present disclosure, the light-emitting function layer 220 includes an effective function region 202. When influence of a film layer thickness of the second electrode 230 on a light-emitting efficiency and a light-emitting uniformity of the light-emitting layer is not considered, the “effective function area” refers to an area where a thickness of at least a part of film layers of the light-emitting function layer is uniform, and a type of “at least a part of film layers” may be selected according to a requirement of an actual process. For example, the “at least a part of film layers” may be any one or a combination of the first function layer 221, the light-emitting layer 222, and the second function layer 223. Specifically, only the thickness of the first function layer 221 is uniform in the effective function area, or the thickness of the first function layer 221 and the light-emitting layer 222 are uniform in the effective function area, or the thickness of the first function layer 221, the light-emitting layer 222, and the second function layer 223 are all uniform in the effective function area. For example, in at least one embodiment of the present disclosure, the first electrode may be provided as an anode, and the second electrode may be provided as a cathode.

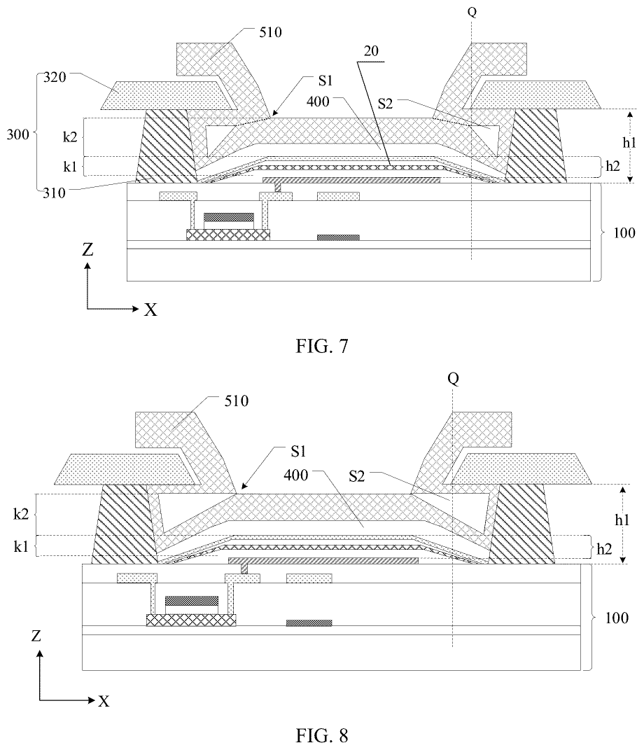

In some embodiments of the present disclosure, a gap between orthographic projections of adjacent first electrodes 210 on the substrate 100 is within an orthographic projection of a surface, facing the substrate 100, of the first end portion 310, that is, a width L4 of a gap between the first electrodes 210 is less than a width L3 of the first end portion 310, so that the first end portion 310 of the isolation structure may cover a groove on the pixel defining layer 330. In other embodiments of the present disclosure, the gap between orthographic projections of the adjacent first electrodes 210 on the substrate 100 coincides with the orthographic projection of the surface, facing the substrate 100, of the first end portion 310, that is, the width L4 of the gap between the first electrodes 210 is equal to the width L3 of the first end portion 310. In this way, a minimum designable width of the first end portion 310 of the isolation structure 300 may be reduced, thereby reducing a minimum spacing between adjacent effective function regions 202, thereby both maintaining the first function layer 221 isolated by the isolation structure 300 and increasing an arrangement density of the light-emitting device 200 (equivalent to pixel density). For example, as shown in FIG. 6 and FIG. 7, along a direction from a middle of the light-emitting device 200 to a corresponding edge, a thickness of the edge portion of a part of the film layers of the light-emitting device 200 gradually decreases. In this way, part of the film layers of the light-emitting device, such as the light-emitting function layer 220 and the second electrode 230, is formed by evaporation assisted by the isolation structure 300, and the isolation structure limits an evaporation range of an evaporation material, therefore, at edges of these film layers, as the distance from the isolation structure becomes closer, the thickness of the film layer becomes less. Correspondingly, a thickness of the light-emitting device 200 at the edge of the second end portion 320 is less than a thickness of a middle portion of the light-emitting device 200. Based on this, a height of the isolation structure 300 (such as a first height below) may be designed to both ensure encapsulation effect of the first encapsulation layer 510 and enable the isolation structure 300 to have a relatively small height, so as to further reduce a partial width of the isolation structure 300 between adjacent first openings 301, so that an aperture ratio, pixel density, and the like of the display panel are improved.

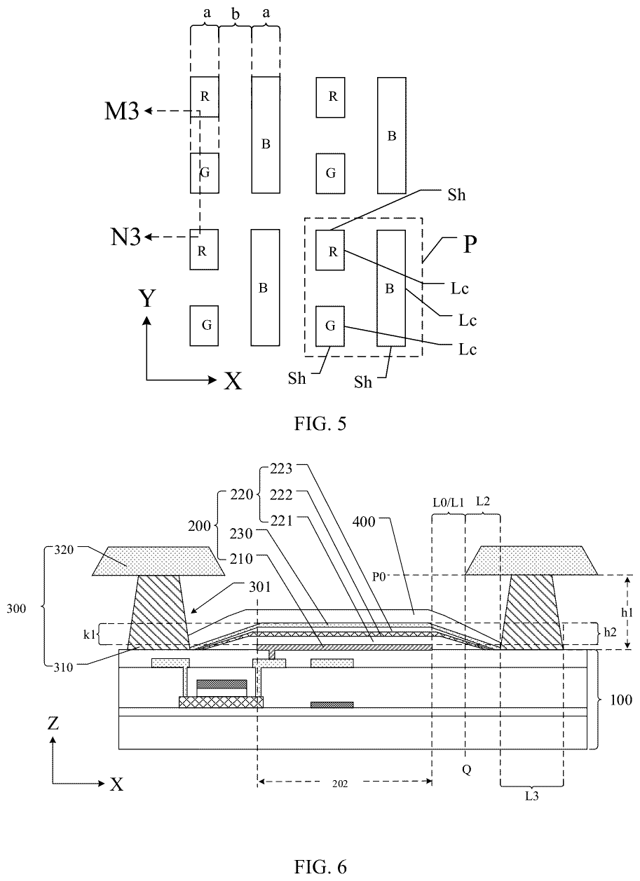

Referring to FIG. 4 and FIG. 5, the display panel includes a plurality of sub-pixels, and the sub-pixel include two opposite long edges Lc and two opposite short edges Sh. A part of the sub-pixels has an edge portion with a gradually decreasing thickness in the direction from the middle of the light-emitting device to the edge only at the short side Sh, and does not have the edge portion gradually decreasing in the direction from the middle of the light-emitting device to the edge at the long edge Lc, so that the aperture ratio of the display panel may be further improved. Additionally, based on a requirement, a part of the sub-pixels may alternatively have an edge portion with a gradually decreasing thickness in the direction from the middle of the light-emitting device to the edge only at the long edge Lc, and may not have the edge portion gradually decreasing in the direction from the middle of the light-emitting device to the edge at the short side Sh.

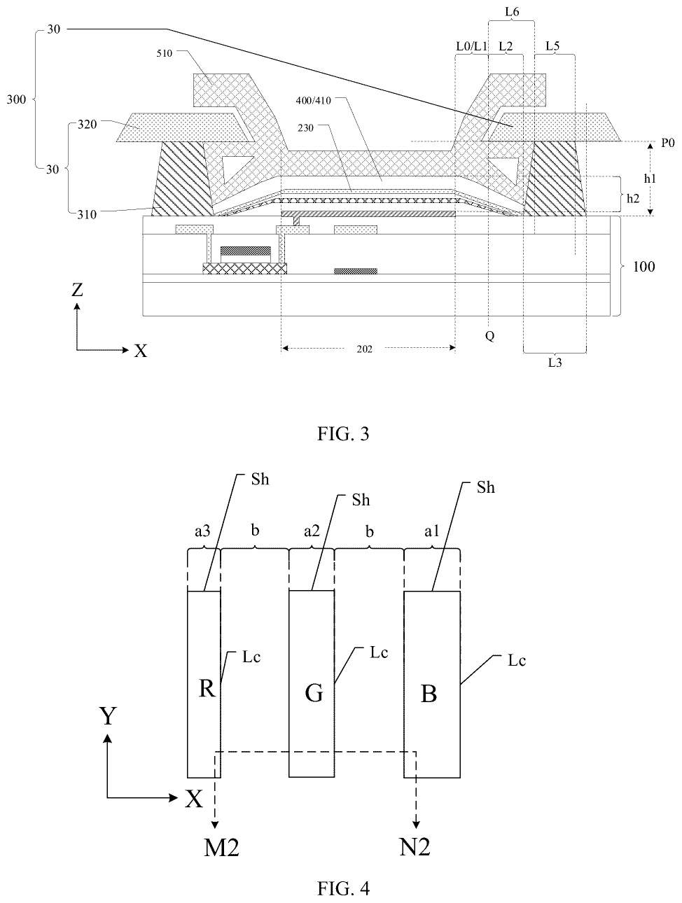

In at least one embodiment of the present disclosure, referring to FIG. 3 again, in a direction perpendicular to a surface where the substrate 100 is located, a distance from the edge of the second end portion 320 to the edge of the first end portion 310 is the first height h1, and at a middle position of the light-emitting device 200, a distance between the first encapsulation layer 510 and the first electrode 210 is a second height h2. A product of the second height h2 and a first thickness coefficient k is a first value, and a difference between the first height h1 and the first value is greater than or equal to an encapsulation safety margin. Based on the foregoing calculation relationship, when the display panel is designed, a distance between the first electrode 210 of the light-emitting device and the first encapsulation layer 510 may be determined based on a film layer structure to be disposed between the first electrode 210 of the light-emitting device and the first encapsulation layer 510, so as to obtain a less value of the first height h1, thereby facilitating finding a less width of the isolation structure 300 designed between adjacent first openings 301 under this condition, so as to improve the aperture ratio and PPI of the display panel.

In at least one embodiment of the present disclosure, within a right section of the light-emitting device, a distance from a position of a surface, facing the substrate 100, of the first encapsulation layer 510 on a straight line passing through the edge of the second end portion 320 and perpendicular to the surface where the substrate 100 is located, to the edge of the first end portion 310 in a direction perpendicular to the surface where the substrate 100 is located is a partition association height h3 (h3 may be referred to as a third height). In a direction perpendicular to the surface where the substrate 100 is located, a distance from the edge of the second end portion 320 to the edge of the first end portion 310 is a first height h1. A difference between the first height h1 and the partition association height h3 (the third height) is greater than or equal to an encapsulation safety margin.

Optionally, M is the ratio of the partition association height to the second height. Optionally, the first thickness coefficient is greater than or equal to M and less than 1, and M is equal to 0.5±0.2. Optionally, the first thickness coefficient is equal to M.

A theoretical value of M is 0.5. During a process of evaporating related film layers with the help of the isolation structure, due to influence of factors such as static electricity, adsorption performance of a used material, a strength of a related material and other factors, the partition association height h3 may deviate from the theoretical value; and correspondingly, based on an actual situation, a value of M may be changed within a range of 0.5±0.2, and a specific value may be obtained through experiments or reference experience.

Optionally, the first thickness coefficient is equal to 0.5. This is beneficial for the first height h1 to have a small value, thereby facilitating an improvement of the pixel density of the display panel.

The encapsulation safety margin is a distance, corresponding to a straight line passing through the edge of the second end portion and perpendicular to the surface where the substrate is located, between a lower surface of the first encapsulation layer and the edge of the second end, and needed to form the first encapsulation layer meeting a function requirement. That is to say, by satisfying a space corresponding to the encapsulation safety margin, the first encapsulation layer formed on a surface of the isolation structure may meet a needed function, such as meeting a requirement in a subsequent process and during product use. The encapsulation safety margin may vary depending on a related structure, a material, and other factors, and may be obtained through an experiment or experience based on a specific situation. When the encapsulation safety margin is determined, if a distance of X value, corresponding to a straight line passing through the edge of the second end portion and perpendicular to the surface where the substrate is located, between a lower surface of the first encapsulation layer and the edge of the second end has been determined to meet the function requirement, but no value less than X has been determined to meet the requirement, and the X value should be determined as the encapsulation safety margin. A minimum value among determined plurality of values meeting the function requirement may be used as the encapsulation safety margin.

For example, when colors of emitted light from the light-emitting devices are different, a light-emitting device with the greatest thickness may be selected as a reference to design parameters such as the first height h1 . . . . For example, the light-emitting device with the greatest thickness may be a light-emitting device emitting red light.

The first encapsulation layer 510 may be formed through chemical vapor deposition, atomic layer deposition, or other methods. If the first height h1 is too small, a film layer thickness of the first encapsulation layer 510 formed at a sidewall of the isolation structure is too small, it leads to an inability to effectively protect the corresponding light-emitting devices and other structures.

In at least one embodiment of the present disclosure, as shown in FIG. 7, at a middle position of the light-emitting device 200, the first encapsulation layer 510 has a first thickness k1 and a second thickness k2, and the second thickness k2 is a thickness of a middle portion, covering the light-emitting device, of the first encapsulation layer 510. The first encapsulation layer 510 covers the light-emitting device 200 and a side surface of a part of the second end portion 320, and the encapsulation safety margin is equal to a product of the second thickness k2 and a second thickness coefficient n.

In an example, as shown in FIG. 7, at a sidewall of the isolation structure 300, a specific structure of the isolation structure, a selection of the second thickness coefficient n, and the second thickness k2 may cause the first encapsulation layer 510 to enclose a closed cavity (at position S2).

For example, in another example, as shown in FIG. 8, at a sidewall of the isolation structure 300, a specific structure of the isolation structure, a selection of the second thickness coefficient n, and a second thickness k2 may make an opening of the cavity of the first encapsulation layer 510 just close.

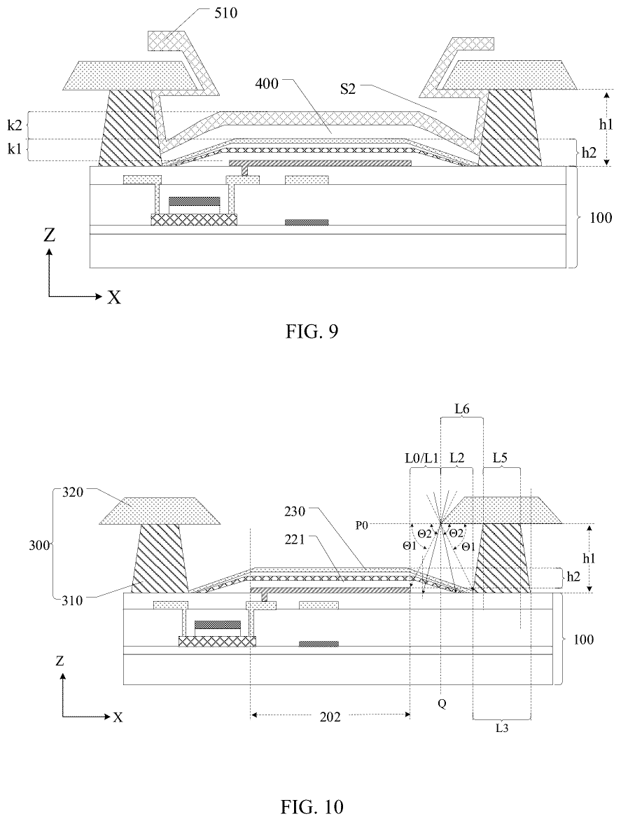

For example, in another example, as shown in FIG. 9, at a sidewall of the isolation structure 300, a specific structure of the isolation structure, a selection of the second thickness coefficient n, and a second thickness k2 may cause the first encapsulation layer 510 to enclose a cavity with an opening. On the premise of ensuring encapsulation effect, a value of the encapsulation safety margin is small, and the isolation structure 300 may have a less height, thereby reducing a width between adjacent first openings to improve the pixel density of the display panel.

For example, the second thickness coefficient n may be a value between 0.2 and 2; Generally, when the second thickness coefficient n may be a value less than 2, corresponding to the isolation structure (as shown in FIG. 6) of some structures, a closed cavity is formed on a side of the isolation structure 300.

For example, the second thickness coefficient n ranges from 0.25-1.2. For example, further, the second thickness coefficient n ranges from 0.3-0.8. For the isolation structure in some structural forms (such as the isolation structure shown in FIG. 6), a greater value of the second thickness coefficient n may better ensure the encapsulation effect, but a distance between pixels is not increased; based on this, selecting values within the range of 0.3-0.8 for the second thickness coefficient n may obtain a better comprehensive effect.

In at least one embodiment of the present disclosure, as shown in FIG. 10, a distance between an orthographic projection of the edge of the second end portion 320 on the surface where the substrate 100 is located and an orthographic projection of the edge of the first end portion 310 on the surface where the substrate 100 is located is a first width L2, within a right section of the light-emitting device 200, an acute angle formed by intersection of a straight line passing through an edge of the second electrode 230 and the edge of the second end portion 320 with the surface where the substrate 100 is located is a first inclination angle Θ1, and the first width L2 is less than a product of the first height h1 and a cotangent value of the first inclination angle Θ1, that is, L2<h1*cot Θ1. The first inclination angle Θ1 mentioned above may correspond to an evaporation angle of the second electrode 230 during evaporation, and by controlling a numerical relationship between the first width L2, first height h1, and the evaporation angle Θ1, the edge of the second electrode 230 is ensured to be overlapped on the isolation structure 300 (for example, the first end portion 310), the second electrode 230 of the light-emitting device 200 is ensured to be connected to an external circuit (for example, a common electrode line or other pixel driving circuit) through the isolation structure 300.

If the less than relationship mentioned above is replaced by an equal to relationship, that is, L2=h1*cot Θ1, then the second electrode 230 may just be in contact with a sidewall of the partition portion 30, while under the relationship of less than mentioned-above, the second electrode 230 may have a certain climbing height on the side surface of the partition portion 30 (such as a raised tail as described below).

In the embodiment of the present disclosure, the edge of the first end portion is an outer edge closest to the substrate in an exposed portion of the first end portion when the light-emitting function layer is prepared, and the edge of the second end portion is an outer edge corresponding to a maximum size of the second end portion in an exposed portion of the isolation structure when the light-emitting function layer is initially prepared.

The “right section of the light-emitting device” may be a section perpendicular to the surface where the substrate is located and parallel to a direction from one first opening to an adjacent first opening, or it may be a normal plane of an edge line of the second end portion and perpendicular to the surface where the substrate is located.

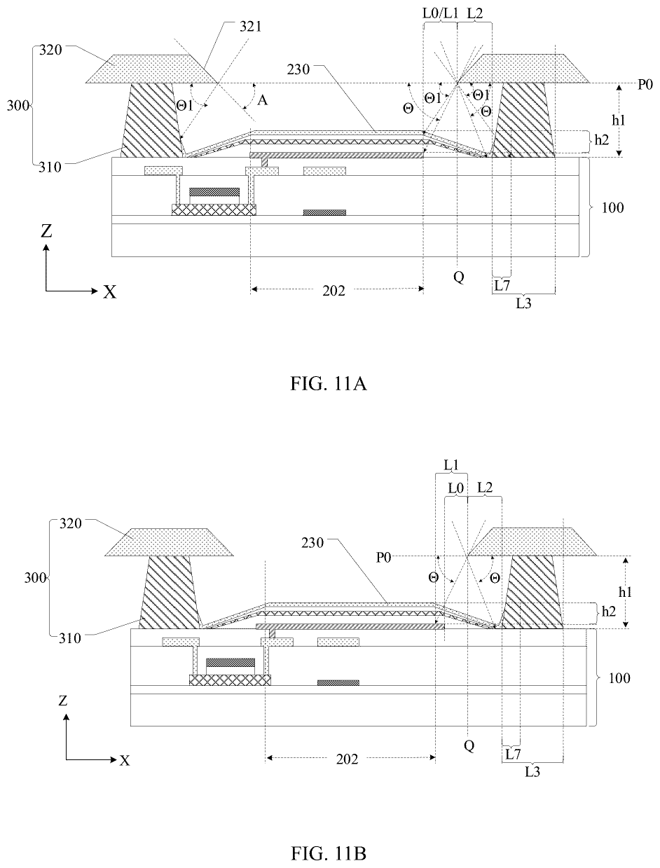

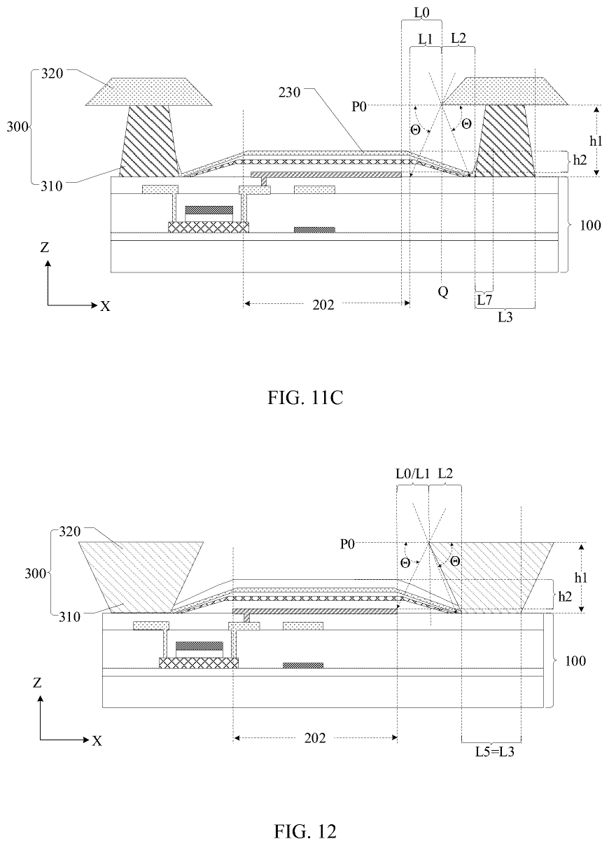

For example, as shown in FIG. 11A, the second electrode 230 has a raised tail portion overlapping the side surface of the first end portion 310, that is, within the right section of the light-emitting device 200, an acute angle formed by intersection of a straight line passing through an edge of the second electrode 230 and the edge of the second end portion 320 with the surface where the substrate 100 is located, is less than an acute angle formed by intersection of a straight line passing through the edge of the first end portion 310 and the edge of the second end portion 320 with the surface where the substrate 100 is located. In this way, in a process of evaporating a conductive material to form the second electrode 230, the conductive material may be evaporated on a sidewall of the first end portion 310 to form the raised tail portion.

For example, in a structure shown in FIG. 11A, a size of the raised tail may be designed based on a dimension L7, that is: on the right section of the light-emitting device, a difference value L7 between a product of the first height h1 and a cotangent value of an acute angle Θ1 formed by intersection of a straight line determined by the edge of the second electrode 230 and the edge of the second end portion 320 with the surface where the substrate 100 is located, and a first width L2 between the edge of the first end portion 310 and the edge of the second end portion 320 in a direction parallel to the surface where the substrate 100 is located. The dimension L7 is greater than or equal to a safety size, and the safety size may be a preset value used to ensure a sufficient contact area between the second electrode 230 and the isolation structure 300, so as to prevent a contact resistance between the second electrode 230 and the isolation structure 300 from being too large. For example, the safety size is related to factors such as a material of the second electrode 230 and magnitude of a current needing to be carried, and may be specifically measured through an experiment or obtained through experience.

For example, as shown in FIG. 11A, within the right section of the light-emitting device 200, an acute angle formed by intersection of a straight line passing through an edge of the light-emitting function layer 220 and the edge of the second end portion 320 with the surface where the substrate 100 is located is an inclination angle of the light-emitting function layer, and the inclination angle of the light-emitting function layer is greater than the first inclination angle Θ1, so that the second electrode 230 may completely cover the light-emitting function layer 220, so that the edge of the second electrode 230 may be connected to the isolation structure 300.

For example, the first width L2 is greater than a product of the first height h1 and a cotangent value of the inclination angle of the light-emitting function layer, so that the edge of the light-emitting function layer 220 does not extend to the sidewall of the isolation structure 300, thereby avoiding electric leakage between a lower side of the light-emitting function layer 220 and the isolation structure 300 to improve the light-emitting efficiency.

For example, referring to FIG. 6 to FIG. 11A, the light-emitting function layer 220 includes a first function layer 221, within the right section of the light-emitting device, an acute angle formed by intersection of a straight line passing through an edge of the first function layer 221 and the edge of the second end portion 320 with the surface where the substrate 100 (parallel to a line PO) is located is a second inclination angle Θ2, and the second inclination angle Θ2 is greater than the inclination angle of the light-emitting function layer. In the light-emitting device 200, the first function layer 221 is covered by another film layer (such as a light-emitting layer, a second function layer, and the like described below) in the light-emitting function layer 220, so that the first function layer 221 is not directly connected to the second electrode 230; in addition, compared with the edge of the entire light-emitting function layer 220, a distance between the edge of the first function layer 221 and the isolation structure 300 is greater, so that the first function layer 221 may be prevented from being connected together by means of the isolation structure 300, thereby avoiding electric leakage between the first function layer 221 and the isolation structure 300 to improve the light-emitting efficiency.

For example, referring to FIG. 6 to FIG. 11A, the light-emitting function layer 220 further includes a light-emitting layer 222 and a second function layer 223, and the light-emitting layer 222 and the second function layer 223 cover the edge of the first function layer 221. The design may prevent the first function layer 221 from crossing the light-emitting layer 222 and the second function layer 223 and directly connecting to the second electrode 230, so as to ensure the light-emitting effect of the light-emitting device 200.

In at least one embodiment of the present disclosure, referring to FIG. 6 to FIG. 11A, the second electrode 230 is formed by using the isolation structure 300, and therefore, at the edge of the second electrode 230, the closer the edge portion of the second electrode 230 is to the isolation structure 300, the less the thickness of the second electrode 230.

Within the right section of the light-emitting device 200, a thickness of the second electrode 230 at a position passing through the edge of the first electrode 210 and being perpendicular to the surface where the substrate 100 is located is less than a thickness of a portion of the second electrode 230 corresponding to a middle position of the light-emitting device 200. In this way, a relatively small first inclination angle Θ1 may be used to achieve better overlapping between the second electrode 230 and the isolation structure 300.

In at least one embodiment of the present disclosure, as shown in FIG. 10 and FIG. 11A, an orthographic projection of an edge of the second end portion 320 on the substrate 100 is located between an orthographic projection of an edge of the first electrode 210 on the substrate 100 and an orthographic projection of the edge of the first end portion 310 on the substrate. This design may prevent the edge of the first electrode 210 from extending below the second end portion 320, so as not to increase a height of a surface of the light-emitting device 200 at the edge of the first electrode 210 due to providing of the first electrode 210, so that enough space for the first encapsulation layer 510 is left to have a good encapsulation effect. Correspondingly, a height of the overall design of the isolation structure 300 may be allowed to be reduced, further reducing the width of the isolation structure 300 between adjacent first openings 301 and achieving good light-emitting quality.

For example, in some designs, as shown in FIG. 11B, the first electrode 210 shown in FIG. 10 and FIG. 11A may be modified, so that distribution of the first electrode 210 extends into a second distance L1, that is, the orthographic projection of the edge of the first electrode 210 on the substrate 100 is located between the orthographic projection of the edge of the second end portion 320 on the substrate 100 and the orthographic projection of the edge of the first end portion 310 on the substrate 100. In this way, on the right section of the light-emitting device 200, a first distance L0 between the orthographic projection of the edge of the first electrode 210 on the substrate 100 and the orthographic projection of the edge of the second end portion 320 on the substrate 100, is less than: a product of a cotangent value of an acute angle (set as Θ) formed by intersection of a line connecting an edge of the light-emitting function layer 220 and the edge of the second end portion 320 with the surface where the substrate 100 is located, and a distance L1 between a middle portion of a lower surface, facing the substrate 100, of the light-emitting function layer 220 and the edge of the second end portion 320 in the direction perpendicular to the surface where the substrate 100 is located. That is, the edge of the first electrode 210 extends into a range of the second distance L1, while within the range of the second distance L1, a thickness of the light-emitting function layer 220 is uneven (gradually thinning). In this way, the first electrode 210 may be ensured to have a large area, and the first electrode 210 may be better ensured to exist in a whole area (for example, the effective function region 202 mentioned above) with a uniform film layer thickness of the light-emitting function layer 220, thereby improving an area of an area (where the film layer thickness of the light-emitting function layer 220 is uniform) with light uniformly emitted of the light-emitting device 200, so as to increase the aperture ratio of the display panel; in addition, the design provides a sufficient margin for alignment accuracy of the first electrode 210 and the isolation structure 300, and even if there is a deviation in positions of the first electrode 210 and the isolation structure 300, the area and position of the area with light uniformly emitted of the light-emitting device 200 are guaranteed to be unaffected.

For example, in some other designs, as shown in FIG. 11A and FIG. 11C, on the right section of the light-emitting device 200, the product L1 of the cotangent value of the acute angle formed by intersection of the line connecting the edge of the light-emitting function layer 220 and the edge of the second end portion 320 with the surface where the substrate 100 is located, and the distance between the middle portion of the lower surface of the light-emitting function layer 220 and the edge of the second end portion 320 in the direction perpendicular to the surface where the substrate 100 is located, is less than or equal to: the distance L0 between the orthographic projection of the edge of the first electrode 210 on the substrate 100 and the orthographic projection of the edge of the second end portion 320 on the substrate 100. In this way, in an area where the light-emitting device 200 is distributed with the first electrode 210, the film layer thickness of the light-emitting function layer 220 is uniform, so that wavelengths of light emitted from a light-emitting area of the light-emitting device 200 are relatively consistent, so as to eliminate a problem of stray light of different colors in the light-emitting device 200.

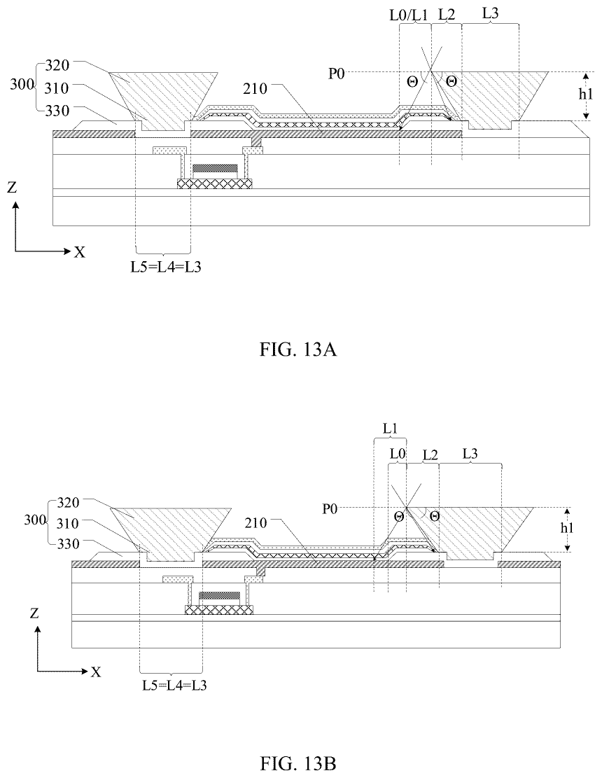

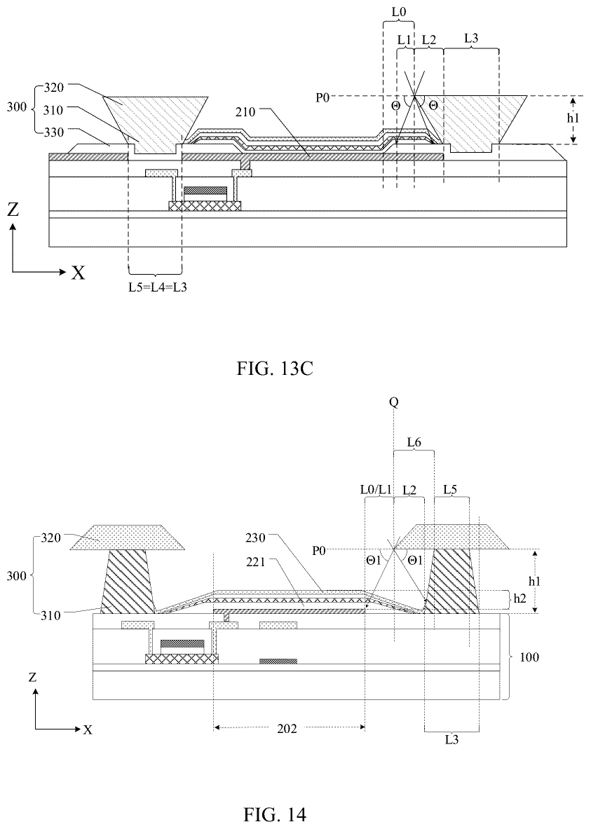

In the embodiments of the present disclosure, the partition portion 30 of the isolation structure 300 may be as shown in FIG. 11A, including a support portion 310 and a block portion 320, or may be as shown in FIG. 12 and FIG. 13A, a section of a portion, located between adjacent sub-pixels, of the isolation structure 300 is generally in an inverted trapezoid shape, and for specific designs of the isolation structures 300 in the two forms, reference may be made to related descriptions in the foregoing embodiments, and details are not described herein again.

For example, as shown in FIG. 10 and FIG. 11A, when the partition portion 30 of the isolation structure 300 is designed to include the support portion 310 and the block portion 320, between two adjacent first openings, a width L5 of a surface, facing the block portion 320, of the support portion 310 is greater than or equal to a safety width. In a direction from any first opening to adjacent another first opening, the width of the isolation structure 300 is greater than or equal to a sum of twice the first width L2, a distance (a difference between L6 and L2) between an orthographic projection of an edge of a top surface of the support portion 310 on the substrate 100 and an orthographic projection of an edge of a bottom surface of the support portion 310 on the substrate 100, and a safety width (a minimum value of L5). The difference between L6 and L2 may be determined based on an inclination degree of the sidewall of the support portion 310, and the greater the difference between L6 and L2 is, the more convenient the edge of the second electrode 320 is attached to the sidewall of the support portion 310; in addition, the less the difference between L6 and L2, and the less the width of the isolation structure 300 between two first openings, the more helpful to improve the pixel density of the display panel. The safety width refers to a width of a surface, facing the block portion 320, of the support portion 310 meeting a function requirement, and the safety width may be obtained through experiment and testing. When the safety width is determined, when a Z value is determined to meet the function requirement and no value less than the Z value meets the function requirement, the Z value should be determined to be the safety width; and a minimum value may be used as the safety width in a plurality of values determined to meet the function requirement.

For example, as shown in FIG. 11A, the partition portion 30 of the isolation structure 300 includes a support portion 310 and a block portion 320 stacked on the substrate 100, and on a right section of the light-emitting device, the block portion 320 has an inclined sidewall 321, and a difference between an acute angle Θ1 formed by intersection of a line connecting an edge of the second electrode and an edge of the block portion 320 with a surface where the substrate 100 is located, and an acute angle A formed by intersection of the sidewall of the block portion with the surface where the substrate 100 is located is greater than or equal to a preset angle. That is, the acute angle A formed by intersection of the sidewall of the block portion with the surface where the substrate 100 is located, is less than the acute angle Θ1 formed by intersection of the line connecting the edge of the second electrode and the edge of the block portion 320 with the surface where the substrate 100 is located, so that in the evaporation process, a surface, away from the substrate 100, of the block portion 320 is prevented to causing unwanted excessive shielding to the evaporation material. For example, the sidewall of the block portion 320 is a surface determined by an edge of a surface, facing the support portion 310, of the block portion 320 and an edge of a surface, facing away from the support portion 310, of the block portion 320. Further, in the embodiments of the present disclosure, the preset angle should satisfy: during an evaporation process of completing all evaporation layers, no more relative obstruction to a normal evaporation material reaching a corresponding position due to attachment of a previous evaporation material to the sidewall. Under the above condition, a specific numerical range of the preset angle is not further limited.

For example, as shown in FIG. 12 and FIG. 13A, when a portion of the partition portion 30 located between two adjacent sub-pixels is generally in an inverted trapezoid shape, and between two adjacent first openings, a width L5 of a surface, facing the substrate 100, of the first end portion 310 may be designed to be greater than or equal to a safety width, and in a direction from any first opening to adjacent another first opening, the width of the isolation structure 300 is greater than or equal to a sum of the safety width and twice the first width L2. A minimum value of the safety width may be designed based on a process (for example, a precision of a process such as photolithography . . . ) of preparing the isolation structure 300. Similarly, the safety width refers to a width satisfying a function requirement, and the safety width may be obtained from experiment and testing or experience. When the safety width is determined, when a Z value is determined to meet the function requirement and no value less than the Z value meets the function requirement, the Z value should be determined to be the safety width; and a minimum value may be used as the safety width in a plurality of values determined to meet the function requirement.

In the embodiments of the present disclosure, the partition portion 30 of the isolation structure 300 may be directly disposed on the substrate 100 as shown in FIG. 11A and FIG. 12, or the partition portion 30 of the isolation structure 300 as shown in FIG. 13A may be separated from the substrate 100 by another structure (such as a pixel defining layer), and under different designs, calculation manners of the width of the isolation structure 300 between the two first openings are different, the specifically calculation manners is as follows.

In some embodiments of the present disclosure, as shown in FIG. 11A to FIG. 11C and FIG. 12, the partition portion 30 of the isolation structure 300 may be directly disposed on the substrate 100, that is, the partition portion 30 of the isolation structure 300 is in direct contact with the substrate 100.

For example, in a specific example, as shown in FIG. 11B, when the partition portion 30 of the isolation structure 300 is in direct contact with the substrate 100 (for example, the pixel defining layer is not provided), on the right section of the light-emitting device, a distance between the orthographic projection of the edge of the first electrode on the substrate and the orthographic projection of the edge of the second end portion on the substrate, is less than: a product of a cotangent value of an acute angle formed by intersection of a line connecting an edge of the light-emitting function layer and the edge of the second end portion with the surface where the substrate is located, and a distance between a middle portion of a lower surface of the light-emitting function layer and the edge of the second end portion in the direction perpendicular to the surface where the substrate is located. That is, the first distance L0 does not coincide with the second distance L1, and a size of the first distance L0 is less than a size of the second distance L1. Specifically, the first distance L0 between the orthographic projection of the edge of the first electrode 210 on the substrate 100 and the orthographic projection of the edge of the second end portion 320 on the substrate 100, is less than: a product of a cotangent value of an acute angle formed by intersection of a line connecting an edge of the light-emitting function layer 220 and the edge of the second end portion 320 with the surface where the substrate 100 is located, and a difference between the first height h1 and a thickness of the first electrode.

For example, in another specific example, as shown in FIG. 11A and FIG. 11C, when the partition portion 30 of the isolation structure 300 is in direct contact with the substrate 100, on the right section of the light-emitting device, the product of the cotangent value of the acute angle formed by intersection of the line connecting the edge of the light-emitting function layer and the edge of the second end portion with the surface where the substrate is located, and the distance between the middle portion of the lower surface of the light-emitting function layer and the edge of the second end portion in the direction perpendicular to the surface where the substrate is located, is less than or equal to: the distance between the orthographic projection of the edge of the first electrode on the substrate and the orthographic projection of the edge of the second end portion on the substrate. In a relationship of equal to, the first distance L0 and the second distance L1 coincide with each other as shown in FIG. 11A or FIG. 12; correspondingly, in a relationship of less than, the first distance L0 does not coincide with the second distance L1, and a size of the first distance L0 is greater than a size of the second distance L1.

Specifically, in the relationship of equal to mentioned above (the first distance L0 coincides with the second distance L1), the first distance L0 between the orthographic projection of the edge of the first electrode 210 on the substrate 100 and the orthographic projection of the edge of the second end portion 320 on the substrate 100, is equal to: the product of the cotangent value of the acute angle formed by intersection of the line connecting the edge of the light-emitting function layer 220 and the edge of the second end portion 320 with the surface where the substrate 100 is located, and the difference between the first height h1 and the thickness of the first electrode.

Specifically, in the relationship of less than mentioned above (the size of the first distance L0 is greater than the size of the second distance L1), a product of the cotangent value of the acute angle formed by intersection of the line connecting the edge of the light-emitting function layer 220 and the edge of the second end portion 320 with the surface where the substrate 100 is located, and the first height h1, is less than: the first distance L0 between the orthographic projection of the edge of the first electrode 210 on the substrate 100 and the orthographic projection of the edge of the second end portion 320 on the substrate 100.

In some other embodiments of the present disclosure, as shown in FIG. 13A, the display panel may further include a pixel defining layer 330, the pixel defining layer 330 is located on the first electrode 210 and located on a side, facing the substrate 100, of the partition portion 30 and defines a second opening 302, the first electrode 210 is exposed from the second opening 302, and the edge of the first end portion 310 is located in an upper surface, facing away from the substrate 100, of the pixel defining layer 330.

For example, as shown in FIG. 13B, on the right section of the light-emitting device 200, a distance L0 between an orthographic projection of an edge of the first electrode 210 exposed from the second opening 302 on the substrate 100 and an orthographic projection of the edge of the second end portion 320 on the substrate 100, is less than: a product L1 of a cotangent value of an acute angle Θ formed by intersection of a line connecting an edge of the light-emitting function layer 220 and the edge of the second end portion 320 with the surface where the substrate 100 is located, and a distance between a middle portion of a lower surface of the light-emitting function layer 220 and the edge of the second end portion 320 in the direction perpendicular to the surface where the substrate 100 is located. In this way, the first electrode 210 may be ensured to exist in a whole area (for example, the effective function region 202 mentioned above) with a uniform film layer thickness of the light-emitting function layer 220, thereby improving an area of an area (where the film layer thickness of the light-emitting function layer 220 is uniform) with light uniformly emitted of the light-emitting device 200, so as to increase the aperture ratio of the display panel.

With regard to the above relationship, when the display panel is provided with the pixel defining layer 330, the first electrode 210 may extend below the isolation structure 300, and correspondingly, the isolation structure 300 is configured to cover a gap between adjacent first electrodes 210. In this case, a position of the edge of the first end portion 310 is raised by the first electrode 210 and the pixel defining layer 330, so that the distance between the middle portion of the lower surface of the light-emitting function layer 220 and the edge of the second end portion 320 in the direction perpendicular to the surface where the substrate 100, is located is equal to a sum of the first height h1 and a thickness of the pixel defining layer 330, that is, on the right section of the light-emitting device 200, a distance L0 between an orthographic projection of an edge of the first electrode 210 exposed from the second opening 302 on the substrate 100 and an orthographic projection of the edge of the second end portion 320 on the substrate 100, is less than: a product L1 of a cotangent value of an acute angle Θ formed by intersection of a line connecting an edge of the light-emitting function layer 220 and the edge of the second end portion 320 with the surface where the substrate 100 is located, and the sum of the first height h1 and the thickness of the pixel defining layer 330.

For example, as shown in FIG. 13A and FIG. 13C, as shown in FIG. 13A and FIG. 13C, on the right section of the light-emitting device 200, the product L1 of the cotangent value of the acute angle Θ formed by intersection of the line connecting the edge of the light-emitting function layer 220 and the edge of the second end portion 320 with the surface where the substrate 100 is located, and the distance between the middle portion of the lower surface of the light-emitting function layer 220 and the edge of the second end portion 320 in the direction perpendicular to the surface where the substrate 100 is located, is less than or equal to the distance L0 between the orthographic projection of the edge of the first electrode 210 exposed from the second opening 302 on the substrate 100 and the orthographic projection of the edge of the second end portion 320 on the substrate 100. In this way, in an area where the light-emitting device 200 is distributed with the first electrode 210, the film layer thickness of the light-emitting function layer 220 is uniform, so that wavelengths of light emitted from the light-emitting area of the light-emitting device 200 are relatively consistent, so as to eliminate a problem of stray light of different colors in the light-emitting device 200.

With regard to the above relationship, when the display panel is provided with the pixel defining layer 330, the first electrode 210 may extend below the isolation structure 300, and correspondingly, the isolation structure 300 is configured to cover the gap between adjacent first electrodes 210. In this case, the position of the edge of the first end portion 310 is raised by the first electrode 210 and the pixel defining layer 330. Therefore, the product L1 of the cotangent value of the acute angle Θ formed by intersection of the line connecting the edge of the light-emitting function layer 220 and the edge of the second end portion 320 with the surface where the substrate 100 is located, and the sum of the first height h1 and the thickness of the pixel defining layer 330, is less than or equal to the distance L0 between the orthographic projection of an edge of the first electrode 210 exposed from the second opening 302 on the substrate 100 and the orthographic projection of the edge of the second end portion 320 on the substrate 100.

For example, the pixel defining layer 330 is an inorganic layer, a portion of the pixel defining layer 330 covering a gap between adjacent first electrodes 210 has a groove conformal with the gap, and a surface, facing the substrate 100, of the first end portion 310 covers the groove. The inorganic pixel defining layer 330 may be designed to have a less thickness, so that there is a less segment difference at the edge of the pixel defining layer 330, so as to improve continuity of the second electrode 230 at the edge; in addition, the design may reduce a degree of increase of the height of the isolation structure 300 due to the arrangement of the pixel defining layer 330; in addition, the first end portion 310 completely covers the groove, thereby eliminating influence of the groove on the isolation structure 300 to ensure the same heights of the edges of the first end portion 310.

For example, the distance between the middle portion of the lower surface of the light-emitting function layer 220 and the edge of the second end portion 320 in the direction perpendicular to the surface where the substrate 100 is located, is equal to the sum of the first height h1 and the thickness of the pixel defining layer 330.

In the embodiments of the present disclosure, the specific shape of the isolation structure and whether to provide the pixel defining layer may be selected based on a specific condition.

For example, in some examples, referring to FIG. 12 again, a portion of the partition portion 30 of the isolation structure 300 between two adjacent sub-pixels is in an inverted trapezoid shape, and may be directly disposed on the substrate 100 to be in direct contact with the substrate 100. For a method of calculating a position relationship between the isolation structure and the first electrode, and the light-emitting function layer, reference may be made to related descriptions in the foregoing embodiments, and not be described herein again.

For example, in some other examples, as shown in FIG. 13A to FIG. 13C, a portion of the partition portion 30 of the isolation structure 300 located between two adjacent sub-pixels is in an inverted trapezoid shape, the display panel includes a pixel defining layer 330, and the partition portion 30 of the isolation structure 300 is disposed on the pixel defining layer 330. For a method of calculating a position relationship between the partition portion 30 and the first electrode, the light-emitting function layer, and the pixel defining layer, reference may be made to related descriptions in the foregoing embodiments, and not be described herein again.

For example, in some other examples, as shown in FIG. 14, the partition portion 30 of the isolation structure 300 is designed to include a support portion 310 and a block portion 320, and the partition portion 30 of the isolation structure 300 may be directly disposed on the substrate 100 (that is, there is no pixel defining layer disposed between the partition portion 30 and the substrate) to be in direct contact with the substrate 100. For a method of calculating a position relationship between the partition portion 30 and the first electrode, and the light-emitting function layer, reference may be made to related descriptions in the foregoing embodiments, and not be described herein again.

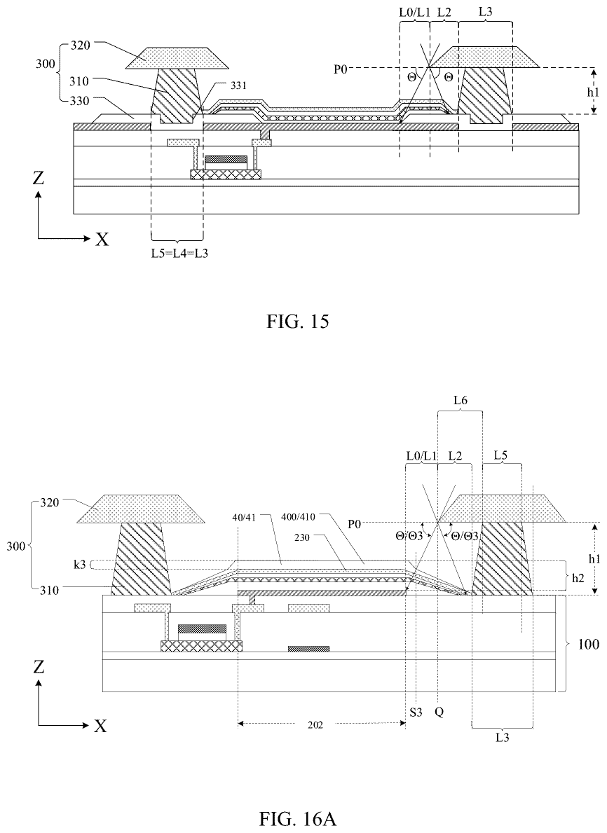

For example, in some other examples, as shown in FIG. 15, the partition portion 30 of the isolation structure 300 is designed to include a support portion 310 and a block portion 320, the display panel includes a pixel defining layer 330, and a partition portion 30 of the isolation structure 300 is disposed on the pixel defining layer 330. For a method of calculating a position relationship between the partition portion 30 and the first electrode, the light-emitting function layer, and the pixel defining layer, reference may be made to related descriptions in the foregoing embodiments, and not be described herein again.

As described above, the method of calculating the width of the isolation structure between the adjacent first openings is described, and the first distance L0 is synchronously calculated in the calculation method, therefore, a distance between two sub-pixels, that is, a distance between the effective function areas, may be obtained, and the pixel density of the display panel may be calculated by combining a specific pixel arrangement and a width of the sub-pixel in each pixel, and a specific calculation method for the pixel density as follows.

For example, in an example, the display panel includes a plurality of pixels, each pixel includes a first sub-pixel, a second sub-pixel, and a third sub-pixel emitting light with sequentially increased wavelengths, the first sub-pixel, the second sub-pixel, and the third sub-pixel respectively include a light-emitting device different from others, the first sub-pixels, the second sub-pixels, and the third sub-pixels are arranged in a plurality of rows and a plurality of columns, respectively, and in each pixel, the first sub-pixel, the second sub-pixel, and the third sub-pixel are sequentially arranged along a row direction, and width directions of the first sub-pixel, the second sub-pixel, and the third sub-pixel are all perpendicular to a column direction, and the number of the first sub-pixel, the number of the second sub-pixels, and the number of the third sub-pixels are equal. In other words, the display panel may include a plurality of pixels, and each pixel includes a plurality of sub-pixels emitting light of different wavelengths, the plurality of sub-pixels of the plurality of pixels include first sub-pixels, second sub-pixels, and third sub-pixels, and the first sub-pixel, the second sub-pixel, and the third sub-pixel respectively include a light-emitting device different from others; the number ratio of the first sub-pixel, the second sub-pixel and the third sub-pixel is 1:1:1; in each pixel, the first sub-pixel, the second sub-pixel and the third sub-pixel are arranged in parallel; and this kind of arrangement manner may be referred to as a first pixel arrangement manner. The arrangement of the pixels of the display panel in the design may be referred to the foregoing related description in the embodiment concerning FIG. 4. For adjustment of structural parameters of the isolation structure, a numerical range of the width of the isolation structure between adjacent first openings varies, and is not limited to the description related to FIG. 4. For details, please refer to related descriptions of the pixel density of the display panel and a manner of calculating the width of corresponding isolation structure in the following embodiments.

For example, in another example, the display panel includes a plurality of pixels, each pixel includes a first sub-pixel, a second sub-pixel, and a third sub-pixel emitting light with sequentially increased wavelengths, the first sub-pixel, the second sub-pixel, and the third sub-pixel respectively include a light-emitting device different from others, the first sub-pixels, the second sub-pixels, and the third sub-pixels are arranged in a plurality of columns, width directions of the first sub-pixel, the second sub-pixel, and the third sub-pixel are all perpendicular to a column direction, a column where the second sub-pixel and the third sub-pixel are located is different from a column where the first sub-pixel is located, in the column where the second sub-pixel and the third sub-pixel are located, the second sub-pixel and the third sub-pixel are alternately arranged, the column where the first sub-pixel is located and the column where the second sub-pixel is located are alternately arranged, and the number of the first sub-pixel, the number of the second sub-pixels, and the number of the third sub-pixels are equal. In other words, the display panel may include a plurality of pixels, and each pixel includes a plurality of sub-pixels emitting light of different wavelengths, the plurality of sub-pixels of the plurality of pixels include first sub-pixels, second sub-pixels, and third sub-pixels, and the first sub-pixel, the second sub-pixel, and the third sub-pixel respectively include a light-emitting device different from others; the number ratio of the first sub-pixel, the second sub-pixel and the third sub-pixel is 1:1:1; in each pixel, the second sub-pixel and the third sub-pixel are arranged in a column or a row and arranged in parallel with the first sub-pixel; and this kind of arrangement manner may be referred to as a second pixel arrangement manner. The arrangement of the pixels of the display panel in the design may be referred to the foregoing related description in the embodiment concerning FIG. 5. For adjustment of structural parameters of the isolation structure, a numerical range of the width (see L in FIG. 5) of the isolation structure between adjacent first openings varies, and is not limited to the description related to FIG. 5. For details, please refer to related descriptions of the pixel density of the display panel and a manner of calculating the width of corresponding isolation structure in the following embodiments.

In at least one embodiment of the present disclosure, as shown in FIG. 16A and FIG. 16B, an acute angle Θ3 formed by intersection of a connecting line from an edge of the optical function unit 41 to the edge of the second end portion 320 with the surface where the substrate 100 is located, is greater than or equal to an acute angle Θ formed by intersection of a connecting line from an edge of the light-emitting function layer to the edge of the second end portion 320 with the surface where the substrate 100 is located, where FIG. 16A shows a positional relationship between the optical function unit 41 and the light-emitting function layer under the equal to relationship, and FIG. 16B shows a positional relationship between the optical function unit 41 and the light-emitting function layer under the greater than relationship. In this way, a portion of the optical function unit 41 having a uniform thickness covers a portion of the light-emitting function layer having a uniform thickness, so that the light emitted by the light-emitting device passes through the portion of the optical function unit 41 having a uniform thickness as much as possible, so as to improve the display effect of the display panel. Even under the relationship of “equal to” (Θ3=Θ) mentioned above, as shown in FIG. 16A, because the optical function unit 41 is located above the light-emitting function layer, an area of a portion of the optical function film layer having a uniform thickness is still greater than an area of the portion of the light-emitting function layer having a uniform thickness, that is, an orthographic projection of the portion of the light-emitting function layer having a uniform thickness on the substrate 100 is within an orthographic projection of the portion of the optical function unit 41 having a uniform thickness on the substrate 100. Specifically, in a structure shown in FIG. 16A, a boundary of the portion of the light-emitting function layer having a uniform thickness coincides with an edge of the first electrode, and a boundary of the portion of the optical function unit 41 having a uniform thickness is located at the position S 3.

when an optical function layer 40 is located below the first encapsulation layer, a thickness K3 of the optical function layer 40 affects encapsulation of the first encapsulation layer, that is, when a specific parameter of the isolation structure is calculated, the thickness K3 of the optical function layer 40 needs to be added.

For example, the optical function unit 41 is located between the light-emitting function layer 220 and the first encapsulation layer 510, at least a part of the first openings 301 are internally provided with the optical function unit 41, and an orthographic projection of a part of an edge portion of the optical function unit 41 on the substrate 100 is within the orthographic projection of the second end portion 320 on the substrate 100. For example, a thickness of an edge portion of the optical function unit 41 gradually decreases in the direction from the middle of the light-emitting device 200 to the corresponding edge. In this way, a thickness of the edge portion of a part of the film layers of the optical function unit 41 gradually decreases, and correspondingly, the film layers may be formed by evaporation assisted by the isolation structure 300, and the isolation structure 300 limits an evaporation range of an evaporation material, therefore, at edges of these film layers, as the distance from the isolation structure becomes closer, the thickness of the film layer becomes less. Correspondingly, a thickness of the light-emitting device 200 at the edge of the second end portion 320 is less than a thickness of a middle portion of the light-emitting device 200. Based on this, a height of the isolation structure 300 (such as a first height below) may be designed to both ensure encapsulation effect of the first encapsulation layer 510 and enable the isolation structure 300 to have a relatively small height, so as to further reduce a partial width of the isolation structure 300 between adjacent first openings 301, so that an aperture ratio, pixel density, and the like of the display panel are improved.

For example, in some embodiments of the present disclosure, on the right section of the light-emitting device, a product of a cotangent value of an acute angle formed by intersection of a line connecting the edge of the optical function unit 41 to the edge of the second end portion with the surface where the substrate is located, and a distance between a middle portion of a lower surface of the optical function unit 41 and the edge of the second end portion in the direction perpendicular to the surface where the substrate is located, is less than or equal to a distance between an orthographic projection of an edge of the first electrode on the substrate and an orthographic projection of the edge of the second end portion on the substrate. A manner of providing the optical function unit 41 in the solution may be referred to related descriptions in the following embodiments (such as an embodiment describing a light conversion unit), and details are not described herein again.

For example, in some other embodiments of the present disclosure, the display panel further includes a pixel defining layer, the pixel defining layer is located on the first electrode and located on a side, facing the substrate, of the partition portion 30 and defines a second opening, the first electrode is exposed from the second opening, and the edge of the first end portion is located in an upper surface of the pixel defining layer. A distance between a middle portion of a lower surface of the optical function unit 41 mentioned above and the edge of the second end portion in the direction perpendicular to the surface where the substrate is located is equal to: a difference between a sum of the first height and a thickness of the pixel defining layer, and a distance between the middle portion of the lower surface of the optical function unit 41 and a middle portion of the first electrode in the direction perpendicular to the surface where the substrate is located. A manner of providing the optical function unit 41 in the solution may be referred to related descriptions in the following embodiments (such as an embodiment describing a light conversion unit), and details are not described herein again.

In the embodiments of the present disclosure, a type of the optical function unit 41 is not limited, and may be designed based on an actual need, and the following describes several design choices of the optical function unit 41.

For example, in at least one embodiment of the present disclosure, as shown in FIG. 16A, the optical function layer 40 may include a light conversion layer 400, and the optical function unit 41 may include a light conversion unit 410. When the light-emitting devices of the display panel are configured to emit light of the same color (the same color may be single primary color light or mixed light), the light conversion layer 400 is provided in the display panel to enable the display panel to have a light conversion function to display a color image and in this design, light-emitting quality of the display panel may be higher.

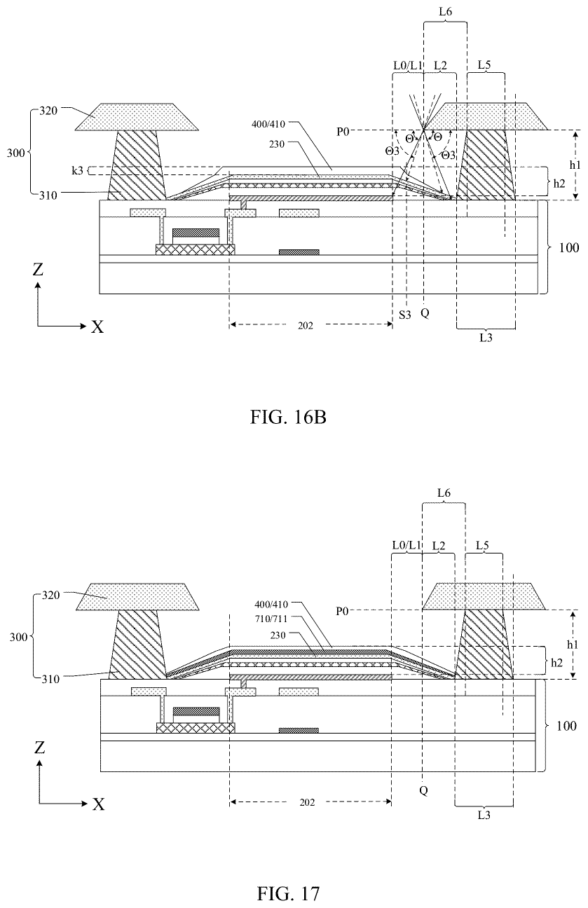

For example, in at least one embodiment of the present disclosure, as shown in FIG. 17, the optical function layer 40 may further include a light extraction layer 710, the light extraction layer 710 includes a plurality of light extraction units 711 respectively located in the first openings, and in the first opening provided with the light conversion unit 410, the light extraction unit is located between the light-emitting function layer and the light conversion unit 410. By providing the light extraction unit 711, light extraction efficiency of the light-emitting device may be improved, so as to improve a brightness of a display image of the display panel.

For example, the light extraction unit 711 includes a first extraction sub-layer as a single-layer structure; or the light extraction unit 711 may be of a multi-layer structure, that is, the light extraction unit 711 includes a first extraction sub-layer, a second extraction sub-layer located on a side, facing the substrate 100, of the first extraction sub-layer, and a third extraction sub-layer located on a side, facing away from the substrate 100, of the first extraction sub-layer, where a refractive index of the second extraction sub-layer and a refractive index of the third extraction sub-layer are both less than a refractive index of the first extraction sub-layer.

For example, the refractive index of the first extraction sub-layer ranges from 2.0-2.3, and further, for example, the refractive index of the first extraction sub-layer ranges from 2.1-2.2.

For example, a thickness of the first extraction sub-layer ranges from 45-75 nm, and further, for example, the thickness of the first extraction sub-layer ranges from 55-65 nm.

For example, the refractive index of at least one of: the second extraction sub-layer and the third extraction sub-layer ranges from 1.4-1.8, and further, for example, the refractive index of at least one of: the second extraction sub-layer and the third extraction sub-layer ranges from 1.5-1.6.

For example, a thickness of at least one of: the second extraction sub-layer and the third extraction sub-layer ranges from 7-30 nm, and further, for example, the thickness of at least one of: the second extraction sub-layer and the third extraction sub-layer ranges from 10-20 nm.

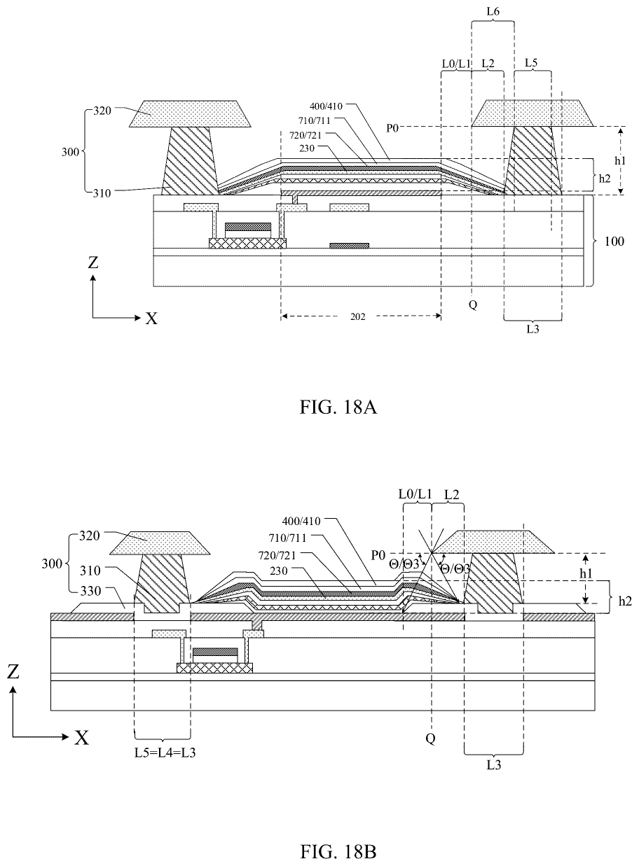

For example, in at least one embodiment of the present disclosure, as shown in FIG. 18A, the optical function layer 40 may further include a light control layer 720, the light control layer 720 includes a plurality of light control units 721 respectively located in the first openings, and in the first opening provided with the light conversion unit 410, the light control unit 721 is located between the light-emitting function layer and the light extraction unit 711. For example, the light control unit 721 may be a lithium fluoride unit, that is, a material of the light control unit 721 includes a lithium fluoride material, so as to adjust refractive indexes of adjacent film layers, so that the light emitted by the light-emitting device is easier to be extracted.

For example, a thickness of the light control unit ranges from 65-100 nm, and further, for example, the thickness of the light control unit ranges from 75-85 nm.

In at least one embodiment of the present disclosure, the optical function unit 41 is provided as at least one type, and the optical function unit 41 is one of an optical conversion unit 410, a light extraction unit 711, a light control unit 721, a filling unit 610 and a light filter unit (see related description in related embodiments); or the optical function unit 41 is provided as at least two types, and the at least two optical function units 41 are different types of the light conversion unit 410, the light extraction unit 711, the light control unit 721, the filling unit 610 and the light filter unit. In this way, when the optical function unit 41 includes the light conversion unit 410, the light-emitting device 200 of the display panel may be configured to emit light of the same color, so that the light-emitting devices 200 may be synchronously prepared, and overall light-emitting quality of the display panel may be improved.

The following describes a calculation manner between structural parameters of the isolation structure, the light-emitting device, and the optical function unit 41 in combination with several design combinations of the optical function unit 41. The light conversion unit only needs to be located on a light-emitting side of the light-emitting function layer, and a specific position of the light conversion unit may be designed based on an actual process requirement. The calculation manner is specifically as follows.

In at least one embodiment of the present disclosure, referring to FIG. 16A, when the optical function layer 40 includes a light conversion layer, an orthographic projection of a part of an edge portion of the light conversion unit 410 on the substrate 100 is within the orthographic projection of the second end portion 320 on the substrate 100, and a thickness of the edge portion of the light conversion unit 410 gradually decreases in the direction from the middle of the light-emitting device to the corresponding edge. The light conversion unit 410 may be formed by evaporation with the help of the isolation structure 300, therefore, a variation law of a film layer thickness of the light conversion unit 410 is substantially the same as a variation law of a film layer thickness of the light-emitting function layer, and influence of a film layer thickness variation of the light conversion unit 410 on encapsulation effect of the first encapsulation layer may refer to the related description of the influence of a film layer thickness variation of the light-emitting function layer on the encapsulation effect of the first encapsulation layer in the foregoing embodiments, and not be elaborated here.

For example, when the isolation structure 300 is directly disposed on the substrate 100, as shown in FIG. 16A to FIG. 18A, the partition portion 30 of the isolation structure 300 is in direct contact with a surface of the substrate 100, and a product of a cotangent value of an acute angle Θ3 formed by intersection of a line connecting an edge of the light conversion unit 410 and the edge of the second end portion 320 with the surface where the substrate 100 is located, and a difference between the first height h1 and a distance between a middle portion of a surface, facing the substrate 100, of the light conversion unit 410 and the edge of the first end portion 310 in the direction perpendicular to the surface where the substrate 100 is located, is equal to or less than (a relationship of less than is shown in the figure): a product L1 of the cotangent value of the acute angle @ formed by intersection of the line connecting the edge of the light-emitting function layer and the edge of the second end portion 320 with the surface where the substrate 100 is located, and a difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light conversion unit 410 is ensured to be uniform in an area where the light-emitting device emits light uniformly.

For example, as shown in FIG. 18B, when the display panel is provided with a pixel defining layer 330, a difference between a sum of the first height h1 and a thickness of the pixel defining layer 330, and the distance between the middle portion of the surface, facing the substrate 100, of the light conversion unit 410 and the edge of the first end portion 310 in the direction perpendicular to the surface where the substrate 100 is located is a design value, and a product of design value and the cotangent value of the acute angle Θ3 formed by intersection of the line connecting the edge of the light conversion unit 410 and the edge of the second end portion 320 with the surface where the substrate 100 is located, is equal to or less than: the product L1 of the cotangent value of the acute angle @ formed by intersection of the line connecting the edge of the light-emitting function layer and the edge of the second end portion 320 with the surface where the substrate 100 is located, and the difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light conversion unit 410 is ensured to be uniform in the area where the light-emitting device emits light uniformly.

For example, the thickness of the pixel defining layer may be a thickness of a portion of the pixel defining layer covering the first electrode.

In the following, for several different positional relationships between the optical function layer 40 and the light-emitting device, a structure of the display panel and a calculation manner for structure parameters of the isolation structure, the light-emitting device, and the optical function unit 41 are described in detail as follows.

In some embodiments of the present disclosure, as shown in FIG. 16A to FIG. 18A, the light conversion layer 400 is located above the second electrode 230 of the light-emitting device, that is, located on a side, facing away from the substrate 100, of the second electrode 230, and in this case, the second height h2 includes a thickness of a portion of the light conversion unit 410 corresponding to a middle position of the light-emitting device.

For example, there is an interval between the edge of the light conversion unit 410 and the isolation structure 300, so that a film layer thickness of the light conversion unit 410 is uniform in a light-emitting area of the light-emitting device; in addition, the edge of the light conversion unit 410 may be prevented from extending to the sidewall of the isolation structure resulting in affecting encapsulation of the first encapsulation layer.

For example, as shown in FIG. 18A and FIG. 18B, the optical function layer 40 includes a light extraction layer 710, the light extraction layer 710 includes a plurality of light extraction units 711 respectively corresponding to the light-emitting devices, and the light extraction unit 711 is located in the first opening, and in this case, the second height h2 includes a thickness of a portion of the light extraction unit 711 corresponding to a middle position of the light-emitting device. For example, the light extraction unit 711 is located between the light-emitting device and the light conversion unit 410.

For example, as shown in FIG. 18A, when the isolation structure 300 is directly disposed on the substrate 100, a product of a cotangent value of an acute angle Θ3 formed by intersection of a line connecting an edge of the light extraction unit 711 and the edge of the second end portion 320 with the surface where the substrate 100 is located, and a difference between the first height h1 and a distance between a middle portion of a surface, facing the substrate 100, of the light extraction unit 711 and the edge of the first end portion 310 in the direction perpendicular to the surface where the substrate 100 is located, is equal to or less than: a product L1 of the cotangent value of the acute angle Θ formed by intersection of the line connecting the edge of the light-emitting function layer and the edge of the second end portion 320 with the surface where the substrate 100 is located, and a difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light extraction unit 711 is ensured to be uniform in an area where the light-emitting device emits light uniformly.

For example, as shown in FIG. 18B, when the display panel is provided with a pixel defining layer 330, a difference between a sum of the first height h1 and a thickness of the pixel defining layer 330, and the distance between the middle portion of the surface, facing the substrate 100, of the light extraction unit 711 and the edge of the first end portion 310 in the direction perpendicular to the surface where the substrate 100 is located is a design value, and a product of design value and the cotangent value of the acute angle Θ3 formed by intersection of the line connecting the edge of the light extraction unit 711 and the edge of the second end portion 320 with the surface where the substrate 100 is located, is equal to or less than: the product L1 of the cotangent value of the acute angle @ formed by intersection of the line connecting the edge of the light-emitting function layer and the edge of the second end portion 320 with the surface where the substrate 100 is located, and the difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light extraction unit 711 is ensured to be uniform in the area where the light-emitting device emits light uniformly.

For example, as shown in FIG. 18A and FIG. 18B, the optical function layer 40 includes a light control layer 720, the light control layer 720 includes a plurality of light control units 721, the light control unit 721 is located between the light extraction unit 711 and the light-emitting device, and the second height h2 includes thicknesses of portions respectively of the light extraction unit 711 and the light control unit 721 corresponding to the middle position of the light-emitting device. For example, the light control unit 721 is a lithium fluoride unit.

For example, as shown in FIG. 18A, when the isolation structure 300 is directly disposed on the substrate 100, a product of a cotangent value of an acute angle Θ3 formed by intersection of a line connecting an edge of the light control unit 721 and the edge of the second end portion 320 with the surface where the substrate 100 is located, and a difference between the first height h1 and a distance between a middle portion of a surface, facing the substrate 100, of the light control unit 721 and the edge of the first end portion 310 in the direction perpendicular to the surface where the substrate 100 is located, is equal to or less than: a product L1 of the cotangent value of the acute angle Q formed by intersection of the line connecting the edge of the light-emitting function layer and the edge of the second end portion 320 with the surface where the substrate 100 is located, and a difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light control unit 721 is ensured to be uniform in an area where the light-emitting device emits light uniformly.

For example, as shown in FIG. 18B, when the display panel is provided with a pixel defining layer 330, a difference between a sum of the first height h1 and a thickness of the pixel defining layer 330, and the distance between the middle portion of the surface, facing the substrate 100, of the light control unit 721 and the edge of the first end portion 310 in the direction perpendicular to the surface where the substrate 100 is located is a design value, and a product of design value and the cotangent value of the acute angle Θ3 formed by intersection of the line connecting the edge of the light control unit 721 and the edge of the second end portion 320 with the surface where the substrate 100 is located, is equal to or less than: the product L1 of the cotangent value of the acute angle Θ formed by intersection of the line connecting the edge of the light-emitting function layer and the edge of the second end portion 320 with the surface where the substrate 100 is located, and the difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light control unit 721 is ensured to be uniform in the area where the light-emitting device emits light uniformly.

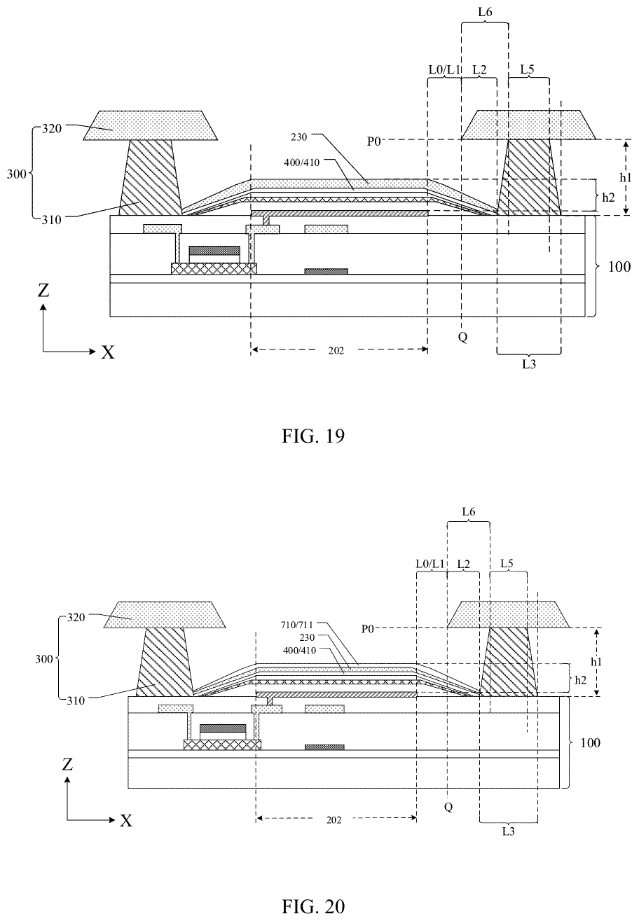

In some other embodiments of the present disclosure, as shown in FIG. 19 to FIG. 21, the light conversion unit 410 is located between the second electrode 230 and the light-emitting function layer, and the second height h2 includes a thickness of a portion of the light conversion unit 410 corresponding to a middle position of the light-emitting device.

For example, as shown in FIG. 20, the optical function layer 40 includes a light extraction layer, the light extraction layer includes a plurality of light extraction units 711 respectively corresponding to the light-emitting devices, the light extraction unit 711 is located in the first opening, and the second height h2 includes a thickness of a portion of the light extraction unit 711 corresponding to a middle position of the light-emitting device. For example, the light extraction unit 711 is located between the light-emitting device and the light conversion unit.

For example, when the isolation structure 300 is directly disposed on the substrate 100, a product of a cotangent value of an acute angle formed by intersection of a line connecting an edge of the light extraction unit 711 and the edge of the second end portion 320 with the surface where the substrate 100 is located, and a difference between the first height h1 and a distance between a middle portion of a surface, facing the substrate 100, of the light extraction unit 711 and the edge of the first end portion 310 in the direction perpendicular to the surface where the substrate 100 is located, is equal to or less than: a product of the cotangent value of the acute angle formed by intersection of the line connecting the edge of the light-emitting function layer and the edge of the second end portion 320 with the surface where the substrate 100 is located, and a difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light extraction unit 711 is ensured to be uniform in an area where the light-emitting device emits light uniformly.

For example, when the display panel is provided with a pixel defining layer, a difference between a sum of the first height h1 and a thickness of the pixel defining layer, and the distance between the middle portion of the surface, facing the substrate 100, of the light extraction unit 711 and the edge of the first end portion 310 in the direction perpendicular to the surface where the substrate 100 is located is a design value, and a product of design value and the cotangent value of the acute angle formed by intersection of the line connecting the edge of the light extraction unit 711 and the edge of the second end portion 320 with the surface where the substrate 100 is located, is equal to or less than: the product of the cotangent value of the acute angle formed by intersection of the line connecting the edge of the light-emitting function layer and the edge of the second end portion 320 with the surface where the substrate 100 is located, and the difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light extraction unit 711 is ensured to be uniform in the area where the light-emitting device emits light uniformly.

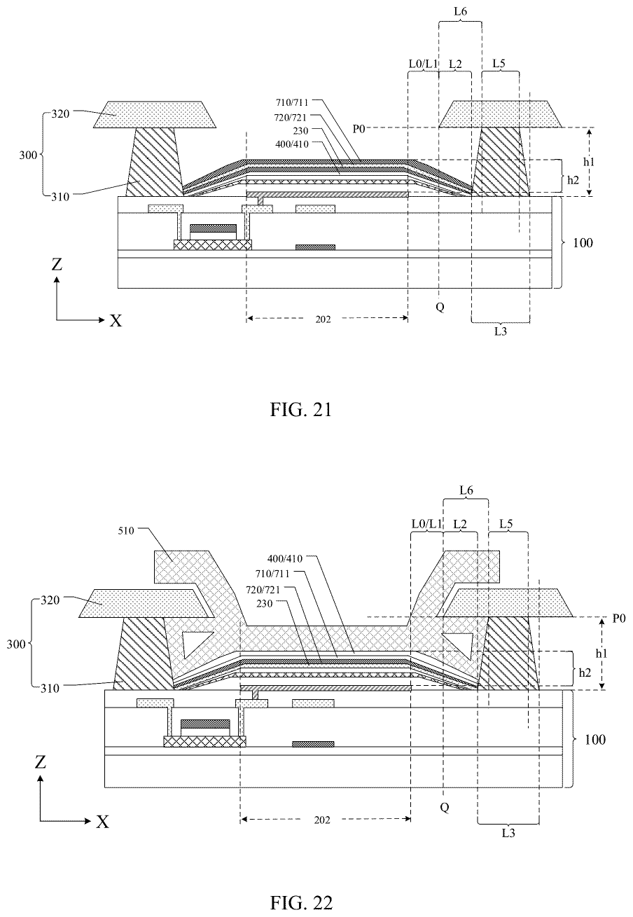

For example, as shown in FIG. 21, the optical function layer 40 includes a light control layer, the light control layer includes a plurality of light control units 721, and the light control unit 721 is located between the light extraction unit 711 and the light-emitting device. The second height h2 includes thicknesses of portions respectively of the light extraction unit 711 and a lithium fluoride unit corresponding to a middle position of the light-emitting device. For example, the light control unit 721 is the lithium fluoride unit.

For example, when the isolation structure 300 is directly disposed on the substrate 100, a product of a cotangent value of an acute angle formed by intersection of a line connecting an edge of the light control unit 721 and the edge of the second end portion 320 with the surface where the substrate 100 is located, and a difference between the first height h1 and a distance between a middle portion of a surface, facing the substrate 100, of the light control unit 721 and the edge of the first end portion 310 in the direction perpendicular to the surface where the substrate 100 is located, is equal to or less than: a product of the cotangent value of the acute angle formed by intersection of the line connecting the edge of the light-emitting function layer and the edge of the second end portion 320 with the surface where the substrate 100 is located, and a difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light control unit 721 is ensured to be uniform in an area where the light-emitting device emits light uniformly.

For example, when the display panel is provided with a pixel defining layer, a difference between a sum of the first height h1 and a thickness of the pixel defining layer, and the distance between the middle portion of the surface, facing the substrate 100, of the light control unit 721 and the edge of the first end portion 310 in the direction perpendicular to the surface where the substrate 100 is located is a design value, and a product of design value and the cotangent value of the acute angle formed by intersection of the line connecting the edge of the light control unit 721 and the edge of the second end portion 320 with the surface where the substrate 100 is located, is equal to or less than: the product of the cotangent value of the acute angle formed by intersection of the line connecting the edge of the light-emitting function layer and the edge of the second end portion 320 with the surface where the substrate 100 is located, and the difference between the first height h1 and the distance between the middle portion of the surface, facing the substrate 100, of the light-emitting function layer and the edge of the first end portion 310 in the direction perpendicular to the surface where the substrate 100 is located. In this way, a film layer thickness of the light control unit 721 is ensured to be uniform in the area where the light-emitting device emits light uniformly.

For example, in the foregoing embodiment, as shown in FIG. 22, an optical function unit 41 may be located below the first encapsulation layer 510, and in this design, when the first height is designed, the thickness of the optical function unit 41 needs to be considered, that is, the distance between the first encapsulation layer and the first electrode includes the thicknesses respectively of the light-emitting function layer, the second electrode, and the optical function unit 41.

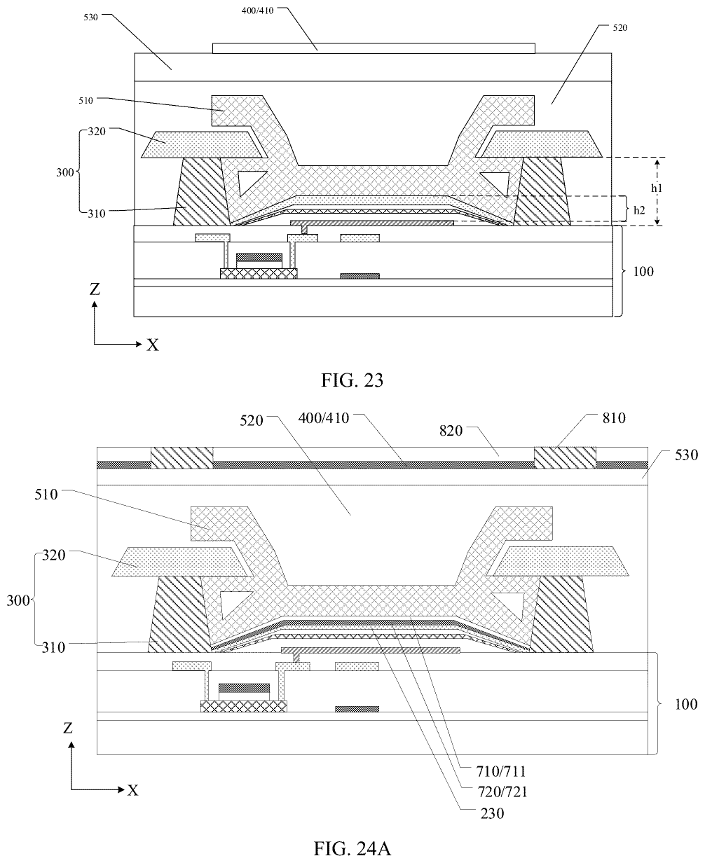

In some other embodiments of the present disclosure, as shown in FIG. 23, a light conversion layer 400 may be located above the first encapsulation layer 510, that is, the light conversion layer is located on a side, facing away from the substrate 100, of the first encapsulation layer 510. In this way, a problem of increasing a height of the isolation structure due to arrangement of the light conversion layer may be eliminated. In this design, the optical function layer 40 may be disposed on a side, facing away from the substrate 100, of the first encapsulation layer (or entire encapsulation layer represented by symbols 510 to 530).

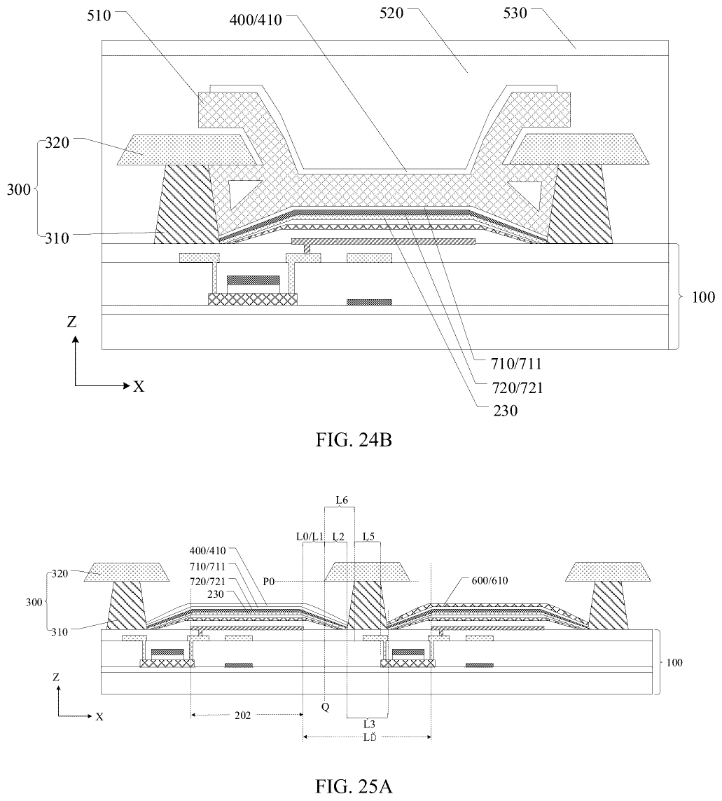

In the embodiments of the present disclosure, when a light conversion layer is located on a side, facing away from the substrate, of the first encapsulation layer, disposing positions of other optical function units 41, such as a light control layer and a light extraction layer . . . , are not limited. For example, in some embodiments, as shown in FIG. 24A, the light conversion layer 400 may be located on a side, facing away from the substrate 100, of the first encapsulation layer 510, and the light control layer 720 and the light extraction layer 710 are located between the first encapsulation layer 510 and the light-emitting device for improving light extraction efficiency of the light-emitting device. In this case, the related design may be referred to in the related explanations in the aforementioned embodiments, and not be elaborated here.

For example, in some other embodiments of the present disclosure, some structures located above the first encapsulation layer 510 may be designed to include a light conversion material to be multiplexed as an optical conversion unit. For example, as shown in FIG. 24B, when a second encapsulation layer 520 (see the related description in the following embodiments, and may be an organic film layer) is disposed on the first encapsulation layer 510, the second encapsulation layer 520 may be designed to include a plurality of multiplexing units, and the multiplexing unit includes a light conversion material to serve as the light conversion unit 410, so that a lightweight and thin design of the display panel is facilitated.

For example, in some other embodiments of the present disclosure, the display panel includes a second encapsulation layer 520 located on a side, away from the substrate, of the first encapsulation layer 510, the second encapsulation layer 520 is an organic encapsulation layer, and a light conversion unit may be a structure located between the first encapsulation layer 510 and the second encapsulation layer 520.

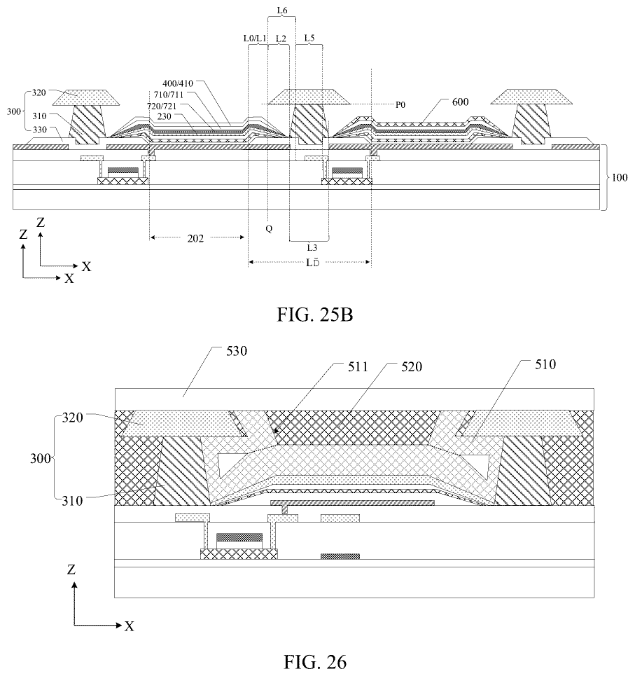

In at least one embodiment of the present disclosure, as shown in FIG. 25A, when a light conversion layer 400 is provided, colors of emergent light from the light-emitting devices are the same, the light conversion unit 410 is configured to convert the emergent light of the light-emitting device into a target color light, and a wavelength of the target color light is greater than a wavelength of the emergent light of the light-emitting device.

For example, in a design, the light-emitting function layer of the light-emitting device includes at least one light-emitting layer, each light-emitting layer is configured to emit a first color light, the light conversion units are at least divided into a first light conversion unit and a second light conversion unit, the first light conversion unit is configured to convert the first color light into a second color light, and the second light conversion unit is configured to convert the first color light into a third color light, and wavelengths of the first color light, the second color light, and the third color light are sequentially increased. For example, the first color light, the second color light, and the third color light are blue light, green light, and red light respectively.

For example, in another design, the light-emitting function layer of the light-emitting device includes at least two light-emitting layers, at least one light-emitting layer is configured to emit a first color light, at least one light-emitting layer is configured to emit a second color light, the light conversion unit 410 is at least divided into a first light conversion unit and a second light conversion unit, the first light conversion unit is configured to convert the first color light into a second color light, and the second light conversion unit is configured to convert the first color light into a third color light, where wavelengths of the first color light, the second color light, and the third color light are sequentially increased, for example, the first color light, the second color light, and the third color light are blue light, green light, and red light respectively; or the wavelengths of the first color light, the third color light, and the second color light are sequentially increased, for example, the first color light, the second color light, and the third color light are blue light, red light, and green light respectively.

For example, a material of the light conversion unit 410 includes a C3PL material. For example, the C3PL material may convert blue light into red light (may be referred to as R-C3 PL) or convert blue light into green light (may be referred to as G-C3PL). For example, the C3PL material may be an organic light-emitting material combination composed of a host material and a guest material. For example, the host material may include at least one of a carbazole derivative, a carbazole fused ring derivative, a carbazoline derivative, a triazine derivative, a pyridine derivative, a pyrimidine derivative, a pyrazine derivative, a pyridazine derivative, a benzimidazole derivative, a 9-9 dimethylfluorene derivative, a 9-9 diphenylfluorene derivative, a spirofluorene derivative, a triarylamine derivative, an anthracene derivative, a phenanthrene derivative, a phthalazine derivative, a pyrene derivative, a perylene derivative, a tetracene derivative, a benzophenone derivative, an oxanthrone derivative, a dibenzofuran derivative, a dibenzothiophene derivative, a quinoline derivative, an isoquinoline derivative, a quinoxaline derivative, a quinazoline derivative, an acridine derivative, a stilbene derivative, or a tetraphenylbutadiene derivative. For example, the guest material may include a narrow-spectrum fluorescent or phosphorescent light-emitting material, and the narrow spectrum fluorescent or phosphorescent light-emitting material includes an anthracene derivative, a pyrene derivative, a boron-nitrogen resonance derivative, an organic material including iridium, platinum and copper.

For example, at least in a case of providing a light conversion unit, a light-emitting type of the light-emitting function layer is fluorescent or phosphorescence. For example, an absorption spectrum and an emission spectrum of the guest material do not overlap.

For example, a film layer thickness of the light conversion unit ranges from 80-1700 nm, and for example, further, the film layer thickness of the light conversion unit ranges from 100-1500 nm, and for example, still further, the film layer thickness of the light conversion unit ranges from 150-800 nm.

For example, as shown in FIG. 25A and FIG. 25B, the display panel further includes a filling layer 600, the filling layer 600 includes a plurality of filling units 610, and the filling unit 610 is located in a first opening not provided with a light conversion unit 410. For example, the light conversion units are disposed in first openings corresponding to sub-pixels R and G, and the light conversion unit does not need to be provided in a first opening corresponding to a sub-pixel B, resulting in a relatively large segment difference in the first opening corresponding to the sub-pixel B, and when structures such as the first encapsulation layer 510 . . . are formed, the segment difference increases a probability of breakage of the first encapsulation layer 510. That is, in the above design, the segment difference at the first opening not provided with the light conversion unit 410 may be reduced by providing the filling layer 600, so as to reduce a risk of breakage of the first encapsulation layer 510, thereby improving the encapsulation effect of the first encapsulation layer 510.

In at least one embodiment of the present disclosure, the first end portion 310 and the second end portion 320 of the isolation structure 300 are of an integrated structure, and in a direction perpendicular to a surface where the substrate 100 is located, a cross-sectional profile of a portion, located between two adjacent sub-pixels, of the partition portion 30 is of an inverted trapezoid, an edge of a bottom of the inverted trapezoidal is an edge of the second end portion 320, and an edge of a top of the inverted trapezoidal is an edge of the first end portion 310.

In at least one embodiment of the present disclosure, the optical function unit 41 is configured to at least include a light filter unit 820 and a light conversion unit 410, the light filter unit 820 is located on a side, away from the substrate 100, of a corresponding light conversion unit 410, and a shielding portion 810 is disposed between adjacent light filter units 820.

For example, the light filter unit 820 is located between a corresponding light conversion unit 410 and a corresponding first encapsulation layer 510, and part of the isolation structure 300 is multiplexed as the shielding portion 810. In at least one embodiment of the present disclosure, as shown in FIG. 24A, the display panel may further include a light filter layer, and the light filter layer is located on a side, facing away from the substrate 100, of the isolation structure 300 and the light conversion layer 400, and includes a shielding portion 810 and a plurality of light filter units 820 respectively corresponding to the light-emitting devices. The shielding portion 810 defines a plurality of light filter openings, the light filter unit 820 is located in the light filter opening, and an orthographic projection of the shielding portion 810 on the substrate 100 is within an orthographic projection of the isolation structure on the substrate 100. The light filter unit 820 may filter out light being not converted by the light conversion unit, and may filter out part of ambient light, so as to filter out stray light, thereby improving display effect of a display image.

In the embodiments of the present disclosure, a block portion of the isolation structure may be designed as a conductive structure, so as to reduce problems such as uneven voltage distribution caused by impedance and voltage drop when the second electrode is driven; or a block portion of the isolation structure may be designed as a film layer having a good bonding strength with the first encapsulation layer, such as an inorganic film layer. A design of the block portion of the isolation structure is specifically as follows.

In at least one embodiment of the present disclosure, as shown in FIG. 26, the first encapsulation layer 510 is in contact with a surface of the block portion, and the first encapsulation layer 510 and the block portion 320 are made of the same material. In this way, the first encapsulation layer 510 and the block portion 320 may be ensured to directly have a reliable bonding strength, so as to reduce a risk of encapsulation failure caused by falling off and cracking of the first encapsulation layer 510.

For example, in some embodiments, as shown in FIG. 26, the first encapsulation layer 510 is composed of a plurality of first encapsulation units respectively covering the first openings, a portion of the first encapsulation layer 510 conformal to the first opening forms an encapsulation groove 511. The display panel further includes a second encapsulation layer 520 and a third encapsulation layer 530. The second encapsulation layer 520 is located on a side, away from the substrate, of the first encapsulation layer 510 and includes a plurality of second encapsulation units. The second encapsulation unit fills the encapsulation groove 511, and a distance from a surface, facing away from the substrate, of the second encapsulation unit to the substrate, is not greater than a distance from a surface, facing away from the substrate, of the block portion 320 to the substrate. The third encapsulation layer 530 is located on a side, facing away from the substrate, of the second encapsulation layer 520 and covers the first opening and the isolation structure. For example, the second encapsulation layer 520 is an organic layer, and the third encapsulation layer 530 is an inorganic layer.

For example, in some other embodiments, the structure shown in FIG. 26 may be modified, where the first encapsulation layer 510 is composed of a plurality of first encapsulation units respectively covering the first openings, a portion of the first encapsulation layer 510 conformal to the first opening forms an encapsulation groove 511. The display panel further includes a second encapsulation layer 520 and a third encapsulation layer 530. The second encapsulation layer 520 is located on a side, away from the substrate, of the first encapsulation layer 510 and includes a plurality of second encapsulation units. The second encapsulation unit fills the encapsulation groove 511, and a distance from a surface, facing away from the substrate, of the second encapsulation unit to the substrate, is less than a distance from a surface, facing away from the substrate, of the block portion 320 to the substrate. The third encapsulation layer 530 is located on a side, facing away from the substrate, of the second encapsulation layer 520 and includes a plurality of third encapsulation units, the third encapsulation unit fills the encapsulation groove 511, and a distance from a surface, facing away from the substrate, of the third encapsulation unit to the substrate, is not greater than a distance from a surface, facing away from the substrate, of the block portion 320 to the substrate. For example, the second encapsulation layer 520 is an organic layer, and the third encapsulation layer 530 is an inorganic layer.

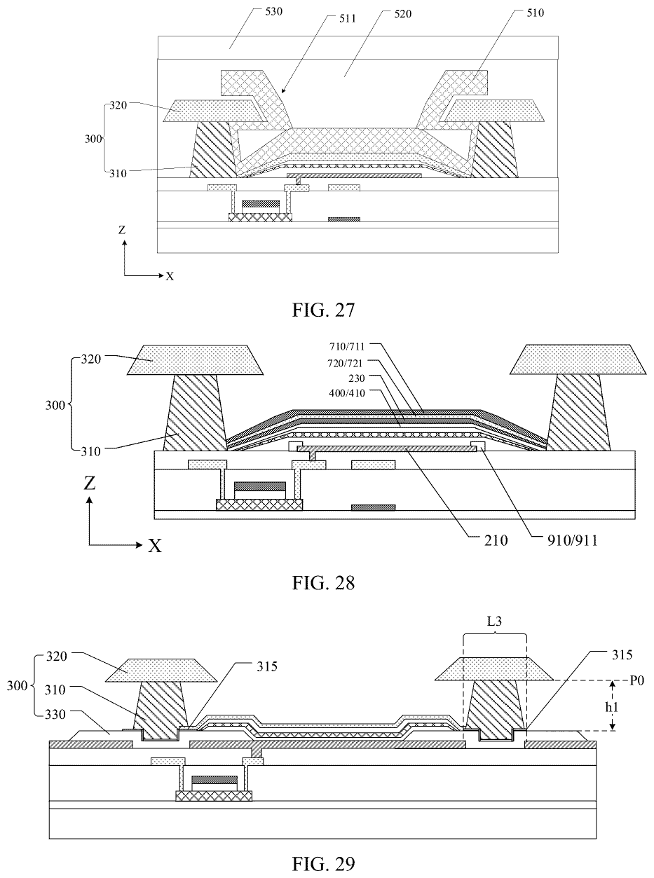

For example, in some other embodiments, as shown in FIG. 27, the first encapsulation layer 510 is composed of a plurality of first encapsulation units respectively covering the first openings, a portion of the first encapsulation layer 510 conformal to the first opening forms an encapsulation groove 511. The display panel further includes a second encapsulation layer 520 and a third encapsulation layer 530. The second encapsulation layer 520 is located on a side, away from the substrate, of the first encapsulation layer 510 and covers the first opening and the isolation structure. The third encapsulation layer 530 is located on a side, facing away from the substrate, of the second encapsulation layer 520 and covers the first opening and the isolation structure. For example, the second encapsulation layer 520 is an organic layer, and the third encapsulation layer 530 is an inorganic layer.

For example, when the first encapsulation layer 510 and the third encapsulation layer 530 are inorganic layers, a material of the first encapsulation layer 510 and the third encapsulation layer 530 may be silicon oxide, silicon nitride, silicon oxynitride, or the like.

For example, in the embodiment of the present disclosure, a first encapsulation unit may be completely located in the first opening as shown in FIG. 26. Alternatively, as shown in FIG. 27, part of a first encapsulation unit extends out of the first opening, and a method of forming the first encapsulation unit in this case may be referred to related descriptions of the preparation method of the display panel in the foregoing embodiments.

In the embodiments of the present disclosure, if a light conversion layer is provided in the display panel, the light-emitting device may not need to be prepared in batches, that is, the first encapsulation layer may be formed as a continuous structure of an entire layer.

In at least one embodiment of the present disclosure, as shown in FIG. 28, the display panel may further include a protective layer 910, the protective layer 910 is an insulating layer, the protective layer 910 includes a plurality of protective units 911, and the protective unit 911 is located between the first electrode 210 and the first end portion 310 to at least cover a sidewall of the first electrode 210. In this way, in a process of preparing the isolation structure 300, the sidewall of the first electrode 210 may be protected by the protective layer 910, so as to prevent the first electrode 210 from side etching, thereby improving a yield of the light-emitting device 200.

On the basis of ensuring the protective unit 911 covering the sidewall of the first electrode 210, a shape, a positional relationship with other structures, and the like of the protective unit 911 may be further designed based on a requirement of an actual process, and is not limited in the embodiments of the present disclosure. For example, in a specific example, the protective unit 911 covers the sidewall of the first electrode 210 and covers an edge portion of an upper surface of the first electrode 210, and has an interval with the first end portion 310 of the isolation structure 300, that is, the protective unit 911 defines a plurality of openings exposing part of the upper surface of the first electrode 210, and an orthographic projection of an edge of the first electrode 210 on the substrate 100 is within an orthographic projection of the protective unit 911 on the substrate 100. For example, in another specific example, the protective unit 911 and the first electrode 210 are in the same layer to cover only the sidewall of the first electrode 210, that is, an orthographic projection of the protective unit 911 on the substrate 100 is located outside an orthographic projection of the first electrode 210 on the substrate 100, and is adjacent to the orthographic projection of the first electrode 210 on the substrate 100, so that the protective unit 911 may be spaced apart from the isolation structure 300 as shown in FIG. 28, or may be adjacent to the isolation structure 300, that is, the protective unit 911 fills a gap between the first electrode 210 and the first end portion 310 of the isolation structure 300; for example, in still another specific example, the protective unit 911 covers the sidewall of the first electrode 210 and a sidewall of the first end portion 310. In this way, a bonding strength between the protective unit 911 and the substrate 100 is higher, and the first electrode 210 is sandwiched between the protective unit 911 and the substrate 100, thereby further reducing the risk of the first electrode 210 falling off from the substrate 100.

For example, the first end portion 310 includes a connecting portion 340 facing a side of the substrate 100, and the connecting portion 340 and the first electrode 210 are in the same layer and made of the same material. In this design, the connecting portion 340 may be synchronously prepared in a process of preparing the first electrode 210, so as to reduce a thickness requirement of the isolation structure; in addition, the connecting portion 340 is disposed between the isolation structure and the substrate 100, so that the risk of the isolation structure 300 falling off from the substrate 100 may be reduced.

In combination with the above description of the edge of the first end portion and the edge of the second end portion of the isolation structure corresponding to different specific structures, the edge of the first end portion corresponds to an edge at the lowermost side of a contact position between an evaporation layer formed with the help of the isolation structure and the first end portion, and is an edge of a lowermost side of an outer leakage of the first end portion before the evaporation layer is formed. For example, as shown in FIG. 29, the first end portion 310 includes a lap joint portion 315 facing a side of the substrate 100, and an edge of the lap joint portion 315 extends outward relative to a portion of the first end portion 310 located on the lap joint portion 315, so that the second electrode 230 is better electrically connected to the support portion 310; a material of the second end portion 320 may include titanium, and a material of the portion of the first end portion 310 located on the lap joint portion 315 may include aluminum; and a material of the lap joint portion 315 may include molybdenum. In this structure, an edge of the lap joint portion 315 is an edge of the first end portion. The edge of the second end portion is an outermost contour edge corresponding to the second end portion, and corresponds to an outermost position where the second end portion shields an evaporation material when an evaporation layer is formed.

In the following, for the specific design of the display panel mentioned above, a pixel pitch between the light-emitting devices, width parameters of each portion of the isolation structure under different pixel pitches, and specific design parameters of each structure in the display panel under different spacing requirements are described. The pixel pitch is in each of two adjacent light-emitting devices, a distance between an edge of a first electrode of a light-emitting device in contact with a corresponding light-emitting function layer, and an edge of a first electrode of adjacent another light-emitting device in contact with a corresponding light-emitting function layer.

At least one embodiment of the present disclosure provides a display panel, the display panel includes a substrate, and an isolation structure and a display function layer 20 located on the substrate, the isolation structure has a first end portion and a second end portion, the second end portion is located on a side, away from the substrate, of the first end portion, the isolation structure defines a plurality of first openings, the light-emitting device includes a first electrode, a light-emitting function layer and a second electrode stacked on the substrate, an orthographic projection of the light-emitting function layer on the substrate is located outside an orthographic projection of the first end portion on the substrate, and is located within an orthographic projection of the second end portion on the substrate, a distance between edges of first electrodes of adjacent light-emitting devices in contact with corresponding light-emitting function layers is a pixel pitch (L ‘as shown in FIG. 25A), and the pixel pitch ranges from 2000-18000 nm.

The pixel pitch L’, shown in FIG. 25A and FIG. 25B, is the first distance L0, and a situation of the first distance L0 coinciding with the second distance L1 is existed.

In some embodiments of the present disclosure, on a right section of the light-emitting device, a cross-sectional profile of a portion, located between two adjacent sub-pixels, of the partition portion 30 is of an inverted trapezoid, an edge of a bottom of the inverted trapezoidal is an edge of the second end portion, and an edge of a top of the inverted trapezoidal is an edge of the first end portion, where a width of the top the inverted trapezoid ranges from 1500-16000 nm. A specific design of the partition portion 30 in this case may be referred to related descriptions in the foregoing embodiments, and details are not described herein again.

In some other embodiments of the present disclosure, the partition portion 30 includes a support portion and a block portion stacked on the substrate, the support portion forms the first end portion, the block portion forms the second end portion, and on a right section of the light-emitting device, cross-sectional profiles of the support portion and the block portion are both of a normal trapezoid, an edge of the second end portion is an edge, facing a surface of the substrate, of the block portion, and an edge of the first end portion is an edge, facing the surface of the substrate, of the support portion, where a width of a bottom of a normal trapezoid corresponding to the support portion ranges from 1258-17000 nm, and a width of a top of a normal trapezoid corresponding to the support portion ranges from 880-15000 nm. A specific design of the partition portion 30 in this case may be referred to related descriptions in the foregoing embodiments, and details are not described herein again.

In at least one embodiment of the present disclosure, the display panel may include a plurality of pixels, and each pixel includes a plurality of sub-pixels emitting light of different wavelengths, the plurality of sub-pixels of the plurality of pixels include a first sub-pixel, a second sub-pixel, and a third sub-pixel, and the first sub-pixel, the second sub-pixel, and the third sub-pixel respectively include a light-emitting device different from others.

Optionally, a number ratio of the first sub-pixel, the second sub-pixel, and the third sub-pixel is 1:1:1.

Optionally, in each pixel, the first sub-pixel, the second sub-pixel, and the third sub-pixel are arranged in a first pixel arrangement manner where the first sub-pixel, the second sub-pixel, and the third sub-pixel are arranged in parallel; alternatively, in each pixel, the first sub-pixel, the second sub-pixel, and the third sub-pixel are arranged in a second arrangement manner where the second sub-pixel and the third sub-pixel are arranged in a column or a row and arranged in parallel with the first sub-pixel. For the two pixel arrangement manners, reference may be made to related descriptions in the foregoing embodiments, and details are not described herein again.

Optionally, the greater a pixel density, at least one of: the less a pixel pitch and the less an average width of the sub-pixels.

In some embodiments of the present disclosure, the partition portion 30 of the isolation structure is in direct contact with the substrate, an edge of a first distance is an edge of a portion of the first electrode contacting the light-emitting function layer in the same light-emitting device, a distance between an orthographic projection of the edge of the second end portion on a surface where the substrate is located and an orthographic projection of the edge of the first end portion on the surface where the substrate is located is a first width, and a distance between the edge of the portion of the first electrode contacting the light-emitting function layer in the same light-emitting device and the orthographic projection of the edge of the second end portion on the surface where the substrate is located is the first distance. In this case, the pixel pitch ranges from 2000-2200 nm, the first distance ranges from 0-1017 nm, and the first width ranges from 148-417 nm; alternatively, the pixel pitch ranges from 2200-2500 nm, the first distance ranges from 0-1050 nm, and the first width ranges from 166-450 nm; alternatively, the pixel pitch ranges from 2500-3200 nm, the first distance ranges from 0-1090 nm, and the first width ranges from 185-490 nm; alternatively, the pixel pitch ranges from 3200-4000 nm, the first distance ranges from 0-1130 nm, and the first width ranges from 203-530 nm; alternatively, the pixel pitch ranges from 4000-6000 nm, the first distance ranges from 0-1170 nm, and the first width ranges from 221-570 nm; alternatively, the pixel pitch ranges from 6000-9000 nm, the first distance ranges from 0-1210 nm, and the first width ranges from 240-610 nm; alternatively the pixel pitch ranges from 9000-13000 nm, the first distance ranges from 0-1300 nm, and the first width ranges from 259-700 nm; alternatively, the pixel pitch ranges from 13000-18000 nm, the first distance ranges from 0-1410 nm, and the first width ranges from 277-810 nm.

For example, in a first case, the partition portion 30 is in direct contact with the substrate, on the right section of the light-emitting device, a product of a cotangent value of an acute angle formed by intersection of a line connecting the edge of the light-emitting function layer and the edge of the second end portion with the surface where the substrate is located, and a distance between a middle portion of a lower surface of the light-emitting function layer and the edge of the second end portion in a direction perpendicular to the surface where the substrate is located, is less than or equal to a distance between an orthographic projection of the edge of the first electrode on the substrate and an orthographic projection of the edge of the second end portion on the substrate. For example, the pixel pitch ranges from 2000-2200 nm, and the first distance ranges from 148-567 nm; alternatively, the pixel pitch ranges from 2200-2500 nm, and the first distance ranges from 166-650 nm; alternatively, the pixel pitch ranges from 2500-3200 nm, and the first distance ranges from 185-740 nm; alternatively, the pixel pitch ranges from 3200-4000 nm, and the first distance ranges from 203-830 nm; alternatively, the pixel pitch ranges from 4000-6000 nm, and the first distance ranges from 221-920 nm; alternatively, the pixel pitch ranges from 6000-9000 nm, and the first distance ranges from 240-1010 nm; alternatively, the pixel pitch ranges from 9000-13000 nm, and the first distance ranges from 259-1150 nm; alternatively, the pixel pitch ranges from 13000-18000 nm, the first distance ranges from 277-1310 nm.

Optionally, for the first case, the partition portion 30 is in direct contact with the substrate mentioned above, in a direction perpendicular to the surface where the substrate is located, a distance from the edge of the second end portion to the edge of the first end portion is a first height, and the first height ranges from 400-2200 nm. Optionally, the pixel pitch ranges from 2000-2200 nm, and the first height ranges from 400-800 nm; alternatively, the pixel pitch ranges from 2200-2500 nm, and the first height ranges from 450-850 nm; alternatively, the pixel pitch ranges from 2500-3200 nm, and the first height ranges from 500-900 nm; alternatively, the pixel pitch ranges from 3200-4000 nm, and the first height ranges from 550-950 nm; alternatively, the pixel pitch ranges from 4000-6000 nm, and the first height ranges from 600-1000 nm; alternatively, the pixel pitch ranges from 6000-9000 nm, and the first height ranges from 650-1100 nm; alternatively, the pixel pitch ranges from 9000-13000 nm, and the first height ranges from 700-1200 nm; alternatively, the pixel pitch ranges from 13000-18000 nm, and the first height ranges from 750-22000 nm.

For example, in a second case, the partition portion 30 is in direct contact with the substrate, on the right section of the light-emitting device, the distance between the orthographic projection of the edge of the first electrode on the substrate and the orthographic projection of the edge of the second end portion on the substrate is less than: the product of the cotangent value of the acute angle formed by intersection of the line connecting the edge of the light-emitting function layer and the edge of the second end portion with the surface where the substrate is located, and the distance between the middle portion of the lower surface of the light-emitting function layer and the edge of the second end portion in the direction perpendicular to the surface where the substrate is located. In this case, the pixel pitch ranges from 2000-2200 nm, the first distance ranges from 0-415 nm, and the first width ranges from 148-417 nm; alternatively, the pixel pitch ranges from 2200-2500 nm, the first distance ranges from 0-446 nm, and the first width ranges from 166-450 nm; alternatively, the pixel pitch ranges from 2500-3200 nm, the first distance ranges from 0-484 nm, and the first width ranges from 185-490 nm; alternatively, the pixel pitch ranges from 3200-4000 nm, the first distance ranges from 0-522 nm, and the first width ranges from 203-530 nm; alternatively, the pixel pitch ranges from 4000-6000 nm, the first distance ranges from 0-560 nm, and the first width ranges from 221-570 nm; alternatively, the pixel pitch ranges from 6000-9000 nm, the first distance ranges from 0-598 nm, and the first width ranges from 240-610 nm; alternatively, the pixel pitch ranges from 9000-13000 nm, the first distance ranges from 0-685 nm, and the first width ranges from 259-700 nm; alternatively, the pixel pitch ranges from 13000-18000 nm, the first distance ranges from 0-790 nm, and the first width ranges from 277-810 nm.

For example, when the partition is in direct contact with the substrate, the display panel further includes at least one optical function layer 40, the optical function layer 40 is located on a side, away from the substrate, of the light-emitting function layer and includes a plurality of optical function units 41 located in first openings, a thickness of an edge portion of a part of film layers of the optical function unit 41 gradually decreases, and for every two adjacent first electrodes, the pixel pitch between edges of portions of first electrodes in contact with light-emitting function layers in the same light-emitting devices ranges from 2074-18000 nm. For a specific type and an arrangement manner of the optical function layer 40, reference may be made to related descriptions in the foregoing embodiments, and details are not described herein again.

In some other embodiments of the present disclosure, the display panel further includes a pixel defining layer, where the pixel defining layer is located on the first electrode and located on a side, facing the substrate, of the partition portion 30 and defines a second opening, the pixel defining layer covers an edge of the first electrode, the second opening exposes the first electrode, and an edge of the second opening coincides with the edge of portion of first electrode in contact with light-emitting function layer in the same light-emitting device, where a distance between an orthographic projection of the edge of the second end portion on a surface where the substrate is located and an orthographic projection of the edge of the first end portion on the surface where the substrate is located is a first width, and a distance between the edge of the portion of the first electrode contacting the light-emitting function layer in the same light-emitting device and the orthographic projection of the edge of the second end portion on the surface where the substrate is located is the first distance. For example, the pixel pitch ranges from 2200-2500 nm, the first distance ranges from 0-1050 nm, and the first width ranges from 148-450 nm; alternatively, the pixel pitch ranges from 2500-3200 nm, the first distance ranges from 0-1090 nm, and the first width ranges from 185-490 nm; alternatively, the pixel pitch ranges from 3200-4000 nm, the first distance ranges from 0-1130 nm, and the first width ranges from 203-530 nm; alternatively, the pixel pitch ranges from 4000-6000 nm, the first distance ranges from 0-1170 nm, and the first width ranges from 221-570 nm; alternatively, the pixel pitch ranges from 6000-9000 nm, the first distance ranges from 0-1210 nm, and the first width ranges from 240-610 nm; alternatively the pixel pitch ranges from 9000-13000 nm, the first distance ranges from 0-1300 nm, and the first width ranges from 259-700 nm; alternatively the pixel pitch ranges from 13000-18000 nm, the first distance ranges from 0-1410 nm, and the first width ranges from 277-810 nm.

For example, in a third case, the display panel includes a pixel defining layer, on the right section of the light-emitting device, the product of the cotangent value of the acute angle formed by intersection of the line connecting the edge of the light-emitting function layer and the edge of the second end portion with the surface where the substrate is located, and the distance between the middle portion of the lower surface of the light-emitting function layer and the edge of the second end portion in the direction perpendicular to the surface where the substrate is located, is less than or equal to a distance between an orthographic projection of an edge of the first electrode exposed from the second opening on the substrate and the orthographic projection of the edge of the second end portion on the substrate. For example, the pixel pitch ranges from 2200-2500 nm, the first distance ranges from 148-650 nm, and the first width ranges from 148-450 nm; alternatively, the pixel pitch ranges from 2500-3200 nm, the first distance ranges from 185-740 nm, and the first width ranges from 185-490 nm; alternatively, the pixel pitch ranges from 3200-4000 nm, the first distance ranges from 203-830 nm, and the first width ranges from 203-530 nm; alternatively, the pixel pitch ranges from 4000-6000 nm, the first distance ranges from 221-920 nm, and the first width ranges from 221-570 nm; alternatively, the pixel pitch ranges from 6000-9000 nm, the first distance ranges from 240-1010 nm, and the first width ranges from 240-610 nm; alternatively, the pixel pitch ranges from 9000-13000 nm, the first distance ranges from 259-1150 nm, and the first width ranges from 259-700 nm; alternatively, the pixel pitch ranges from 13000-18000 nm, the first distance ranges from 277-1310 nm, and the first width ranges from 277-810 nm.

Optionally, for the third case, the display panel includes the pixel defining layer mentioned above, in a direction perpendicular to the surface where the substrate is located, a distance from the edge of the second end portion to the edge of the first end portion is a first height, and the first height ranges from 400-2200 nm. Optionally, the pixel pitch ranges from 2200-2500 nm, and the first height ranges from 400-850 nm; alternatively, the pixel pitch ranges from 2500-3200 nm, and the first height ranges from 500-900 nm; alternatively, the pixel pitch ranges from 3200-4000 nm, and the first height ranges from 550-950 nm; alternatively, the pixel pitch ranges from 4000-6000 nm, and the first height ranges from 600-1000 nm; alternatively, the pixel pitch ranges from 6000-9000 nm, and the first height ranges from 650-1100 nm; alternatively, the pixel pitch ranges from 9000-13000 nm, and the first height ranges from 700-1200 nm; alternatively, the pixel pitch ranges from 13000-18000 nm, and the first height ranges from 750-22000 nm.

For example, in a fourth case, the display panel includes a pixel defining layer, on the right section of the light-emitting device, the distance between the orthographic projection of the edge of the first electrode exposed from the second opening on the substrate and the orthographic projection of the edge of the second end portion on the substrate is less than: the product of the cotangent value of the acute angle formed by intersection of the line connecting an edge of the light-emitting function layer and the edge of the second end portion with the surface where the substrate is located, and a distance between the middle portion of the lower surface of the light-emitting function layer and the edge of the second end portion in the direction perpendicular to the surface where the substrate is located. For example, the pixel pitch ranges from 2200-2500 nm, the first distance ranges from 0-446 nm, and the first width ranges from 148-450 nm; alternatively, the pixel pitch ranges from 2500-3200 nm, the first distance ranges from 0-484 nm, and the first width ranges from 185-490 nm; alternatively, the pixel pitch ranges from 3200-4000 nm, the first distance ranges from 0-522 nm, and the first width ranges from 203-530 nm; alternatively, the pixel pitch ranges from 4000-6000 nm, the first distance ranges from 0-560 nm, and the first width ranges from 221-570 nm; alternatively, the pixel pitch ranges from 6000-9000 nm, the first distance ranges from 0-598 nm, and the first width ranges from 240-610 nm; alternatively, the pixel pitch ranges from 9000-13000 nm, the first distance ranges from 0-685 nm, and the first width ranges from 259-700 nm; alternatively, the pixel pitch ranges from 13000-18000 nm, the first distance ranges from 0-790 nm, and the first width ranges from 277-810 nm.

For example, when the display panel includes a pixel defining layer, the display panel further includes at least one optical function layer 40, the optical function layer 40 is located on a side, away from the substrate, of the light-emitting function layer and includes a plurality of optical function units 41 located in first openings, a thickness of an edge portion of a part of film layers of the optical function unit 41 gradually decreases, and for every two adjacent first electrodes, the pixel pitch between edges of portions of first electrodes in contact with light-emitting function layers in the same light-emitting devices ranges from 2274-18000 nm. For a specific type and an arrangement manner of the optical function layer 40, reference may be made to related descriptions in the foregoing embodiments, and details are not described herein again.

For example, at least one embodiment of the present disclosure provides a display device. The display device may include the display panel in any one of the above embodiments, and the display device may be any product or component having a display function, such as a television, a digital camera, a mobile phone, a watch, a tablet computer, a notebook computer, and a navigator . . . .

The above are only preferred embodiments of the present disclosure and are not intended to limit the present disclosure, and any modification, equivalent replacement, and the like made within the spirit and principle of the present disclosure shall fall within the protection scope of the present disclosure.

What is claimed is:

1. A display panel, comprising:
a substrate;
an isolation structure, located on the substrate and comprising a partition portion, wherein the partition portion comprises a first end portion and a second end portion, the second end portion is located on a side, away from the substrate, of the first end portion, an orthographic projection of the first end portion on the substrate is within an orthographic projection of the second end portion on the substrate, and the isolation structure defines a plurality of first openings;
a display function layer, located on the substrate and comprising a plurality of light-emitting devices correspondingly located in the plurality of first openings, wherein the light-emitting device comprises a first electrode, a light-emitting function layer and a second electrode stacked on the substrate, and each of the plurality of first openings limit one of the plurality of light-emitting devices;
a first encapsulation layer, located on a side, away from the substrate, of the display function layer; and
at least one optical function layer, located on a side, away from the substrate, of the light-emitting function layer and comprising a plurality of optical function units;
wherein an orthographic projection of a part of an edge portion of a part of film layers of the light-emitting device on the substrate is within the orthographic projection of the second end portion on the substrate.

2. The display panel according to claim 1, wherein a thickness of the edge portion of a part of the film layers of the light-emitting device gradually decreases in a direction from a middle of the light-emitting device to an edge of the light-emitting device; wherein
the optical function unit is located between the light-emitting function layer and the first encapsulation layer, and at least one of the plurality of first openings is internally provided with the optical function unit; and
the optical function unit is located between the light-emitting function layer and the first encapsulation layer, an orthographic projection of a part of an edge portion of the optical function unit on the substrate is within the orthographic projection of the second end portion on the substrate, and a thickness of the edge portion of the optical function unit gradually decreases in the direction from the middle of the light-emitting device to the edge of the light-emitting device.

3. The display panel according to claim 2, wherein
in a direction perpendicular to a surface where the substrate is located, a distance from an edge of the second end portion to an edge of the first end portion is a first height; and within a right section of the light-emitting device, a distance from a position of a surface, facing the substrate, of the first encapsulation layer on a straight line passing through the edge of the second end portion and perpendicular to the surface where the substrate is located, to the edge of the first end portion in a direction perpendicular to the surface where the substrate is located is a partition association height, and a difference between the first height and the partition association height is greater than or equal to an encapsulation safety margin; or
in the direction perpendicular to the surface where the substrate is located, the distance from the edge of the second end portion to the edge of the first end portion is the first height, and at a middle position of the light-emitting device, a distance between the first encapsulation layer and the first electrode is a second height, a product of the second height and a first thickness coefficient is a first value, and a difference between the first height and the first value is greater than or equal to an encapsulation safety margin; wherein the first thickness coefficient is greater than or equal to M and less than 1, and M is a ratio of the partition association height to the second height.

4. The display panel according to claim 3, wherein at the middle position of the light-emitting device, the first encapsulation layer has a second thickness, wherein
the first encapsulation layer covers the light-emitting device and a side surface of a part of the second end portion, and the encapsulation safety margin is equal to a product of the second thickness and a second thickness coefficient;
the first encapsulation layer forms a closed cavity on a side surface of the isolation structure, and the second thickness coefficient is between 0.2 and 2; and
the display panel comprises a plurality of sub-pixels, each of the plurality of sub-pixels comprises two opposite long sides and two opposite short sides, a part of the plurality of sub-pixels has an edge portion with a gradually decreasing thickness in the direction from the middle of the light-emitting device to the edge of the light-emitting device only at each of the two opposite short sides, and does not have the edge portion gradually decreasing in the direction from the middle of the light-emitting device to the edge of the light-emitting device at the two opposite long sides.

5. The display panel according to claim 3, wherein
a distance between an orthographic projection of the edge of the second end portion on the surface where the substrate is located and an orthographic projection of the edge of the first end portion on the surface where the substrate is located is a first width;
within the right section of the light-emitting device, an acute angle formed by intersection of a straight line passing through an edge of the second electrode and the edge of the second end portion with the surface where the substrate is located is a first inclination angle, and the first width is less than a product of the first height and a cotangent value of the first inclination angle;
the second electrode has a raised tail portion overlapping a side surface of the first end portion;
within the right section of the light-emitting device, an acute angle formed by intersection of a straight line passing through an edge of the light-emitting function layer and the edge of the second end portion with the surface where the substrate is located is an inclination angle of the light-emitting function layer, and the inclination angle of the light-emitting function layer is greater than the first inclination angle;
the first width is greater than a product of the first height and a cotangent value of the inclination angle of the light-emitting function layer;
the light-emitting function layer comprises a first function layer, within the right section of the light-emitting device, an acute angle formed by intersection of a straight line passing through an edge of the first function layer and the edge of the second end portion with the surface where the substrate is located is a second inclination angle, and the second inclination angle is greater than the inclination angle of the light-emitting function layer;
the light-emitting function layer further comprises a light-emitting layer and a second function layer, and the light-emitting layer and the second function layer cover the edge of the first function layer; and
within the right section of the light-emitting device, a thickness of the second electrode at a position passing through an edge of the first electrode and perpendicular to the surface where the substrate is located is less than a thickness of a portion of the second electrode corresponding to the middle position of the light-emitting device.

6. The display panel according to claim 3, wherein an orthographic projection of the edge of the second end portion on the substrate is located between an orthographic projection of an edge of the first electrode on the substrate and an orthographic projection of the edge of the first end portion on the substrate; wherein
on the right section of the light-emitting device, a distance between the orthographic projection of the edge of the first electrode on the substrate and the orthographic projection of the edge of the second end portion on the substrate is less than a product of a cotangent value of an acute angle formed by intersection of a line connecting an edge of the light-emitting function layer and the edge of the second end portion with the surface where the substrate is located, and a distance between a middle portion of a lower surface of the light-emitting function layer and the edge of the second end portion in the direction perpendicular to the surface where the substrate is located; or
on the right section of the light-emitting device, the product of the cotangent value of the acute angle formed by intersection of the line connecting the edge of the light-emitting function layer and the edge of the second end portion with the surface where the substrate is located, and the distance between the middle portion of the lower surface of the light-emitting function layer and the edge of the second end portion in the direction perpendicular to the surface where the substrate is located, is less than or equal to the distance between the orthographic projection of the edge of the first electrode on the substrate and the orthographic projection of the edge of the second end portion on the substrate.

7. The display panel according to claim 3, further comprising a pixel defining layer, wherein the pixel defining layer is located on the first electrode and located on a side, facing the substrate, of the partition portion and defines a second opening, the first electrode is exposed from the second opening, and the edge of the first end portion is located in an upper surface of the pixel defining layer; wherein
on the right section of the light-emitting device, a distance between an orthographic projection of an edge of the first electrode exposed from the second opening on the substrate and an orthographic projection of the edge of the second end portion on the substrate is less than a product of a cotangent value of an acute angle formed by intersection of a line connecting an edge of the light-emitting function layer and the edge of the second end portion with the surface where the substrate is located, and a distance between a middle portion of a lower surface of the light-emitting function layer and the edge of the second end portion in the direction perpendicular to the surface where the substrate is located; or
on the right section of the light-emitting device, the product of the cotangent value of the acute angle formed by intersection of the line connecting the edge of the light-emitting function layer and the edge of the second end portion with the surface where the substrate is located, and the distance between the middle portion of the lower surface of the light-emitting function layer and the edge of the second end portion in the direction perpendicular to the surface where the substrate is located, is less than or equal to the distance between the orthographic projection of the edge of the first electrode exposed from the second opening on the substrate and the orthographic projection of the edge of the second end portion on the substrate; wherein
the pixel defining layer is an inorganic layer, a portion of the pixel defining layer covering a gap between adjacent first electrodes has a groove conformal with the gap, and a surface, facing the substrate, of the first end portion covers the groove; and
the distance between the middle portion of the lower surface of the light-emitting function layer and the edge of the second end portion in the direction perpendicular to the surface where the substrate is located is equal to a sum of the first height and a thickness of the pixel defining layer.

8. The display panel according to claim 1, further comprising a protective layer, wherein the protective layer is an insulating layer, the protective layer comprises a plurality of protective units, and each of the plurality of protective units is located between the first electrode and the first end portion; and
the protective unit covers a sidewall of the first electrode and has an interval with the first end portion of the isolation structure; or the protective unit covers the sidewall of the first electrode and a sidewall of the first end portion.

9. The display panel according to claim 3, wherein the optical function unit is located between the second electrode and the first encapsulation layer, and the second height comprises a thickness of a part, corresponding to a middle position of the light-emitting device, of the optical function unit; wherein
the optical function unit is configured to comprise at least one type, and the optical function unit is one of an optical conversion unit, a light extraction unit, a light control unit, a filling unit and a light filter unit; or the optical function unit is configured to comprise at least two types, and the at least two optical function units are different types of the light conversion unit, the light extraction unit, the light control unit, the filling unit and the light filter unit;
on the right section of the light-emitting device, an acute angle formed by intersection of a connecting line from an edge of the optical function unit to the edge of the second end portion with the surface where the substrate is located, is greater than or equal to an acute angle formed by intersection of a connecting line from an edge of the light-emitting function layer to the edge of the second end portion with the surface where the substrate is located;
on the right section of the light-emitting device, a product of a cotangent value of an acute angle formed by intersection of a line connecting the edge of the optical function unit to the edge of the second end portion with the surface where the substrate is located, and a distance between a middle portion of a lower surface of the optical function unit and the edge of the second end portion in the direction perpendicular to the surface where the substrate is located, is less than or equal to a distance between an orthographic projection of an edge of the first electrode on the substrate and an orthographic projection of the edge of the second end portion on the substrate; and
the display panel further comprises a pixel defining layer, the pixel defining layer is located on the first electrode and located on a side, facing the substrate, of the partition portion and defines a second opening, the first electrode is exposed from the second opening, and the edge of the first end portion is located in an upper surface of the pixel defining layer, and a distance between a middle portion of a lower surface of the optical function unit and the edge of the second end portion in the direction perpendicular to the surface where the substrate is located is equal to: a difference between a sum of the first height and a thickness of the pixel defining layer, and a distance between the middle portion of the lower surface of the optical function unit and a middle portion of the first electrode in the direction perpendicular to the surface where the substrate is located.

10. The display panel according to claim 1, wherein an optical function unit is located on a side, away from the substrate, of the first encapsulation layer; wherein
the display panel further comprises a second encapsulation layer located on a side, away from the substrate, of the first encapsulation layer, and the second encapsulation layer is an organic encapsulation layer and comprises a multiplexing unit multiplexed as an optical conversion unit; or
the display panel further comprises a second encapsulation layer located on a side, away from the substrate, of the first encapsulation layer, the second encapsulation layer is an organic encapsulation layer, and the optical conversion unit is located between the first encapsulation layer and the second encapsulation layer.

11. The display panel according to claim 9, wherein the light-emitting function layers of the plurality of light-emitting devices are all configured to emit a first color light; the optical function unit comprises the light conversion unit, the light conversion unit comprises at least one of: a first light conversion unit and a second light conversion unit, the first light conversion unit is configured to convert the first color light into a second color light, the second light conversion unit is configured to convert the first color light into a third color light, and wavelengths of the first color light, the second color light, and the third color light are sequentially increased; wherein
the first color light, the second color light and the third color light emit blue light, green light and red light respectively, a material of the first light conversion unit comprises G-C3PL, and a material of the second light conversion unit comprises R-C3PL;
the light-emitting function layer is of a stacked structure;
a light-emitting type of the light-emitting function layer is fluorescent or phosphorescence;
the light conversion unit is located on a side, away from the substrate, of the second electrode; and
an edge of the light conversion unit has an interval with the isolation structure.

12. The display panel according to claim 9, wherein the light-emitting function layer of the light-emitting device comprises at least two light-emitting layers, at least one light-emitting layer is configured to emit a first color light, at least one light-emitting layer is configured to emit a second color light, the light conversion unit comprises at least one of: a first light conversion unit and a second light conversion unit, the first light conversion unit is configured to convert the first color light into the second color light, and the second light conversion unit is configured to convert the first color light into a third color light, and wavelengths of the first color light, the second color light, and the third color light are sequentially increased, or wavelengths of the first color light, the third color light, and the second color light are sequentially increased; wherein
the first color light, the second color light and the third color light emit blue light, green light and red light respectively, a material of the first light conversion unit comprises G-C3PL, and a material of the second light conversion unit comprises R-C3PL; or, the first color light, the second color light and the third color light emit blue light, red light and green light respectively, a material of the first light conversion unit comprises R-C3PL, and a material of the second light conversion unit comprises G-C3PL; and
a light-emitting type of the light-emitting function layer is fluorescent or phosphorescence.

13. The display panel according to claim 11, wherein a C3PL material comprises an organic light-emitting material combination composed of a host material and a guest material; wherein
the host material comprises at least one of a carbazole derivative, a carbazole fused ring derivative, a carbazoline derivative, a triazine derivative, a pyridine derivative, a pyrimidine derivative, a pyrazine derivative, a pyridazine derivative, a benzimidazole derivative, a 9-9 dimethylfluorene derivative, a 9-9 diphenylfluorene derivative, a spirofluorene derivative, a triarylamine derivative, an anthracene derivative, a phenanthrene derivative, a phthalazine derivative, a pyrene derivative, a perylene derivative, a tetracene derivative, a benzophenone derivative, an oxanthrone derivative, a dibenzofuran derivative, a dibenzothiophene derivative, a quinoline derivative, an isoquinoline derivative, a quinoxaline derivative, a quinazoline derivative, an acridine derivative, a stilbene derivative, or a tetraphenylbutadiene derivative;
the guest material comprises a narrow-spectrum fluorescent or phosphorescent light-emitting material, and the narrow spectrum fluorescent or phosphorescent light-emitting material comprises an anthracene derivative, a pyrene derivative, a boron-nitrogen resonance derivative, an organic material comprising iridium, platinum and copper;
an absorption spectrum and an emission spectrum of the guest material do not overlap; and
a film layer thickness of the light conversion unit ranges from 80-1700 nm.

14. The display panel according to claim 9, wherein the optical function unit is configured to at least comprise the filling unit and the light conversion unit, the light conversion unit comprises a red light conversion unit disposed on a side, away from the substrate, of a light-emitting function layer of a light-emitting device emitting red light and a green light conversion unit disposed on a side, away from the substrate, of a light-emitting function layer of a light-emitting device emitting green light, and the filling unit is disposed on a side, away from the substrate, of a light-emitting function layer of a light-emitting device emitting blue light.

15. The display panel according to claim 9, wherein the optical function unit is configured to at least comprise the light extraction unit located between a corresponding light-emitting device and a corresponding light conversion unit or located on a side, away from the substrate, of the light conversion unit; wherein
the light extraction unit comprises a first extraction sub-layer; or the light extraction unit comprises a first extraction sub-layer, a second extraction sub-layer located on a side, facing the substrate, of the first extraction sub-layer, and a third extraction sub-layer located on a side, facing away from the substrate, of the first extraction sub-layer, wherein a refractive index of the second extraction sub-layer and a refractive index of the third extraction sub-layer are both less than a refractive index of the first extraction sub-layer;
the refractive index of the first extraction sub-layer ranges from 2.0-2.3;
a thickness of the first extraction sub-layer ranges from 45-75 nm;
at least one of: the refractive index of the second extraction sub-layer and the third extraction sub-layer ranges from 1.4-1.8; and
a thickness of at least one of: the second extraction sub-layer and the third extraction sub-layer ranges from 7-30 nm.

16. The display panel according to claim 9, wherein the optical function unit is configured to at least comprise a light control unit located on a side, away from the substrate, of a corresponding light extraction unit; wherein
the light control unit is located between the corresponding light extraction unit and a corresponding light conversion unit;
a material of the light control unit comprises a LIF material; and
a thickness of the light control unit ranges from 65-100 nm.

17. The display panel according to claim 1, wherein the partition portion comprises a support portion and a block portion stacked on the substrate, the support portion forms the first end portion, and the block portion forms the second end portion;
the first encapsulation layer is in contact with a surface of the block portion, and the first encapsulation layer and the block portion are made of a same material; and
the support portion is provided with a dividing hole in a grid shape, the dividing hole divides the support portion into a plurality of sub-support portions, the block portion covers and fills the dividing hole, the support portion is of a conductive structure, the block portion is of an insulating structure, and the second electrode is connected to a corresponding sub-support portion.

18. The display panel according to claim 1, wherein
the partition portion comprises a support portion and a block portion stacked on the substrate, and on a right section of the light-emitting device, the block portion has an inclined sidewall, and a difference between an acute angle formed by intersection of a line connecting an edge of the second electrode and an edge of the second end portion with a surface where the substrate is located, and an acute angle formed by intersection of the inclined sidewall of the block portion with the surface where the substrate is located is greater than or equal to a preset angle;
the first end portion and the second end portion of the partition portion are of an integrated structure, and in the direction perpendicular to the surface where the substrate is located, a cross-sectional profile of a portion, located between two adjacent sub-pixels, of the partition portion is of an inverted trapezoid, an edge of a bottom of the inverted trapezoidal is an edge of the second end portion, and an edge of a top of the inverted trapezoidal is an edge of the first end portion;
the optical function unit is configured to at least comprise a light filter unit and a light conversion unit, the light filter unit is located on a side, away from the substrate, of a corresponding light conversion unit, and a shielding portion is disposed between adjacent light filter units; and
the light filter unit is located between a corresponding light conversion unit and the first encapsulation layer, and part of the isolation structure is multiplexed as the shielding portion.

19. The display panel according to claim 1, wherein a distance between edges of first electrodes of adjacent light-emitting devices in contact with corresponding light-emitting function layers is a pixel pitch, and the pixel pitch ranges from 2000-18000 nm.

20. A display device, comprising the display panel according to claim 1.
